(19) United States
(12) Patent Application Publication
(10) Pub. No.: US 2002/0118053 A1
(43) Pub. Date: Aug. 29, 2002

(54) PLL device

(75) Inventors: Yasuaki Sumi, Tottori-shi (JP); Katsu Horikoshi, Osaka (JP); Hisayoshi Uchiyama, Osaka (JP)

Correspondence Address: WILLIAM E. PELTON, c/o Cooper & Dunham LLP, 1185 Avenue of the Americas, New York, NY, 10036, US

(73) Assignee: Sanyo Electric Co., Ltd.

(21) Appl. No.: 10/107,553

(22) Filed: Mar. 26, 2002

Related U.S. Application Data
(63) Continuation of application No. PCT/JP00/06022, filed on Sep. 5, 2000.

(30) Foreign Application Priority Data
Sep. 30, 1999 (JP) 11-278772
Oct. 29, 1999 (JP) 11-308605
Oct. 29, 1999 (JP) 11-308606
Nov. 22, 1999 (JP) 11-331474
Nov. 22, 1999 (JP) 11-331475
Sep. 5, 2000 (JP) PCT/JP00/06022

(51) Int. Cl. H03L 7/06

(52) U.S. Cl. 327/157

(57) ABSTRACT

The PLL device includes means (6) for generating a, plurality of reference signals (FR1, FR2, FR3, FR4) having mutually differing phases, a variable frequency divider (11, 12, 13, 14) for dividing, in synchronization with the phases of a plurality of the reference signals, a frequency of an output signal (FO) of a voltage-controlled oscillator (15) that produces a signal having a frequency responsive to a control voltage (CV) supplied to generate a plurality of feedback signals (FV1, FV2, FV3, FV4) having mutually differing phases, phase comparators (7, 17, 8, 18, 9, 19, 10, 20) for comparing phases between the reference signals and the feedback signals corresponding to the reference signals respectively to produce a plurality of error signals (ER1, ER2, ER3, ER4), a low-pass filter (21) for filtering the error signals output from the phase comparators to produce the control voltage, and a control means (16, 26, 27) for controlling the number of the phase comparators that output the error signals to the low-pass filter in accordance with a phase difference between at least one of a plurality of the feedback signals and the reference signal corresponding to the one of a plurality of the feedback signals.

### BACKGROUND OF THE INVENTION

1. Field of the Invention

The present invention relates to a PLL device.

2. Background Art

As shown, for example, in the drawing at page 32 of “SANYO TECHNICAL REVIEW” Vol.10, No.1, February 1978, a PLL device that generates signals of various frequencies from a reference signal having a certain frequency is known. Such a PLL device includes a reference oscillator generating a reference signal RF, a voltage-controlled oscillator generating an output signal FO responsive to a control voltage CV, a variable frequency divider dividing the frequency of the output signal FO to generate a feedback signal FV, a phase comparator comparing the phase of the feedback signal FV with the phase of the reference signal to generate an error signal ER, and a low-pass filter generating the control voltage CV in response to the error signal ER.

The locking time in this PLL device, or the time needed to synchronize the output signal with the reference signal in phase is determined uniquely as a function of the frequency if the device is designed optimally, and can not be shortened.

The inventor of this application tried to shorten the lock-up time (the time needed for the phase of the output signal to match the phase of the reference signal) by providing phase comparators and variable frequency dividers in multiple stages so that phase comparisons are performed multiple times during one period of the signal. However, the lock-up time was not shortened much actually. The inventor tried to track down the cause, and found it to be that the phase comparators interfered with each other as a locked state approached, which prevented smooth establishment of lock.

It is also found that since the conventional PLL device switches the phase comparators to be in use from multiple stages to a single stage when the locked state approaches, that is, since the gate of one phase comparator is kept open and the gates of the other phase comparators are closed, closing and opening timings of the gates have to be extremely precise, and therefore, it has a disadvantage that lock failure easily arises.

It has also a problem that the manufacturing cost is high since some lock detector for detecting the approach of the locked state is necessary. In addition, it has a problem of having a large electric power consumption since a plurality of the variable frequency dividers must be powered even after lock is completed.

Furthermore, the conventional PLL device has another problem that, if the frequency-division ratio of the variable frequency divider is increased, stability and converging speed of the device are lowered since the lock-up time is prolonged.

The inventor tried to track down the cause and found it to be as follows. An overall gain (loop gain) K of the PLL device is equal to (KP·KV) IN, where KP is a gain of a phase comparator, and KV is again of a voltage-controlled oscillator. Accordingly, when the frequency-division ratio N is increased, the overall gain K falls and, as a result, the lock-up time is prolonged. In addition, since the natural angular frequency and the damping factor of the loop determined by the value of the K become small and deviate from optimum values, stability and converging speed of the device are lowered.

An object of the present invention is to provide a PLL device in which the lock-up time is short, lock is established smoothly, lock failure does not arise, and electric power consumption is small.

Another object of the present invention is to provide a less expensive PLL device in which the lock-up time is short, there is no interference between phase comparators, and any lock detector for switching the phase comparators to be in use from multiple stages to a single stage is unnecessary.

Still another object of the invention is to provide a PLL device in which the lock-up time is short, there is no interference between phase comparators, any lock detector for switching the phase comparators to be in use from multiple stages to a single stage is unnecessary, and precise timings for gate opening and closing are not required.

Still another object of the invention is to provide a PLL device in which output periods of phase comparators do not overlap with each other so that the phase comparators do not interfere with each other, lock is established smoothly, and the lock-up time is short.

Yet another object of the invention is to provide a PLL device in which the lock-up time is not prolonged and stability and converging speed of the device are not lowered even when the frequency-division ratio of a variable frequency divider is increased.

### DISCLOSURE OF THE INVENTION

A PLL device according to a first embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with phases of a plurality of the reference signals, a frequency of an output signal (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (7, 17, 8, 18, 9, 19, 10,20) for comparing phases between the reference signals and the feedback signals corresponding to the reference signals to produce a plurality of error signal (ER1, ER2, ER3, ER4);

a control voltage generating means (21) for producing the control voltage (CV) to be supplied to the voltage-controlled oscillator from the error signals output from the phase comparison means; and

a control means (16, 26, 27) that stops production of a specific one of a plurality of the error signals in accordance with a phase difference between at least one of a plurality of the feedback signals and a reference signal corresponding to the one of a plurality of the feedback signals.

The phase comparison means may be comprised of a plurality of phase comparators having charge pumps (17, 18, 19, 20) whose outputs are connected to the control voltage generating means (21), the control means bringing a phase comparator that should stop production of the error signal to a high-impedance state.

The phase, comparators (7, 8, 9, 10) may have detectors (7a, 8a, 9a, 10a) for detecting a state in which phase difference between the reference signal and the feedback signal is smaller than a predetermined value, the control means bringing at least specific one of the phase comparators to the high-impedance state when a detector of at least one of the phase comparators has detected said state.

The control means may break connection between the phase comparator that should stop outputting the error signal and the control voltage generating means and, after a lapse of a predetermined time, break connection between the variable frequency divider connected to the phase comparator whose connection with the control voltage generating means has been broken and the voltage-controlled oscillator.

A PLL device according to a second embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with phases of a plurality of the reference signals, a frequency of an output signal (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (57, 17, 58, 18, 59, 19, 60, 20) for comparing phases between the reference signals and the feedback signals corresponding to the reference signals to produce a plurality of error signals (ER1, ER2, ER3, ER4); and

a control voltage generating means (21) for producing the control voltage (CV) to be supplied to the voltage-controlled oscillator from the error signals output from the phase comparison means;

wherein the phase comparison means has a first dead zone (D1) used for producing at least one specific error signal (ER1) that is one of a plurality of the error signals, and a second dead zone (D2) used for producing the other error signals (ER2, ER3, ER4).

The phase comparison means may be comprised of a first phase comparator (57) having a smaller dead zone and a second phase comparator (58, 59, 60) having a larger dead zone, both the first phase comparator and the second phase comparator supplying the error signals to the control voltage generating means (21) while phase difference between the output signal (FO) and the reference signal (FR) is large, only the first phase comparator supplying the error signal to the control voltage generating means after the phase difference becomes small.

The second phase comparator (58, 59, 60) may be provided with a first delay circuit (40) for delaying an incoming reference signal and a second delay circuit (47) for delaying an incoming feedback signal.

A PLL device according to a third embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with phases of a plurality of the reference signals, a frequency of an output signal (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (67, 17, 68, 18, 69, 19, 70, 20) for comparing phases between the reference signals and the feedback signals corresponding to the reference signals to produce a plurality of error signals (ER1, ER2, ER3, ER4); and

a control voltage generating means (21) for producing the control voltage (CV) to be supplied to the voltage-controlled oscillator from the error signals output from the phase comparison means;

wherein the phase comparison means has a first dead zone (C1) used for producing at least one specific error signal (ER1) that is one of a plurality of the error signals, and a second dead zone (C2, C3, C4) used for producing the other error signals (ER2, ER3, ER4), a span of the second dead zone being selectable from among a plurality of predetermined values (C2, C3, C4).

The phase comparison means may be comprised of a plurality of phase comparators at least one of which is provided with a plurality of selectable delay circuits (60, 61, 62, 74, 75, 76) for delaying an input signal.

Each of a plurality of the delay circuits may be comprised of inverters connected in series.

By connecting selection circuits to the outputs of a plurality of the delay circuits, an output of any delay circuit connected to a selection circuit supplied with a specific control signal can be selected.

A plurality of the delay circuits may be comprised of a plurality of delay circuits (60, 61, 62) for delaying an incoming reference signal and a plurality of delay circuits (74, 75, 76) for delaying an incoming feedback signal.

A PLL device according to a fourth embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with phases of a plurality of the reference signals, a frequency of an output signal (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (7, 17, 8, 18, 9, 19, 10,20) for comparing phases between the reference signals and the feedback signals corresponding to the reference signals to produce a plurality of error signals (ER1, ER2, ER3, ER4);

a control voltage generating means (21) for producing the control voltage (CV) to be supplied to the voltage-controlled oscillator from the error signals output from the phase comparison means; and

a control means (26 to 31) for setting, in synchronization with the phases of a plurality of the reference signals (FR1, FR2, FR3, FR4), outputting periods (S1, S2, S3 . . . ) during which the phase comparison means outputs a plurality of the error signals (ER1, ER2, ER3, ER4) to the control voltage generating means.

It is possible to set the outputting periods such that they do not overlap with each other.

A suspension period (R1, R2, R3, R4, R5) during which productions of the error signals are all stopped may be interposed between neighboring outputting periods.

The rising or falling edges of the reference signals may be situated at approximately the centers of the outputting periods respectively.

A PLL device according to a fifth embodiment of the invention includes:

a voltage-controlled oscillator (102) producing an output signal of a frequency responsive to a control voltage (CV) supplied;

a variable frequency divider (103) dividing a frequency of the output signal (FO) of the voltage-controlled oscillator to produce a feedback signal of a frequency which is 1/N (N being a positive integer) of the frequency of the output signal;

a phase comparator (106) comparing phases between the feedback signal and the reference signal, a charge pump (109) outputting an error signal (PU, PD) in response to a comparison result of the phase comparator;

a low-pass filter (110) filtering the error signal supplied from the charge pump to produce the control voltage, and a control means (104, 105, 111, 117, 118) controlling a gain of the charge pump in accordance with a value of the N.

A variant of the PLL device according to the fifth embodiment of the invention includes:

a voltage-controlled oscillator (102) producing an output signal of a frequency responsive to a control voltage (CV) supplied;

a variable frequency divider (103) dividing a frequency of the output signal (FO) of the voltage-controlled oscillator to produce a feedback signal of a frequency which is 1/N (N being a positive integer) of the frequency of the output signal;

a phase comparator (106) comparing phases between the feedback signal and the reference signal to output an error signal (PU, PD);

a charge pump (109) outputting a first voltage (GND) when the feedback signal leads the reference signal and outputting a second voltage (VDD) when the feedback signal lags the reference signal;

a low-pass filter (110) filtering an output of the charge pump to produce the control voltage; and

a control means (104, 105, 111, 117, 118) for maintaining a current flowing between the charge pump and the low-pass filter at a value in accordance with a value of the N.

The control means may include a control unit (104) for computing the value of the N in response to a command from outside, a latch circuit (105) for storing a digital signal corresponding to the value of the N, and a D/A converter (111) for converting the digital signal into a voltage signal (D) to be supplied to the charge pump.

The charge pump may include a first switching unit (Q7) connected between an output terminal (116) of the charge pump and a terminal of the first voltage (GND), conductivity of the first switching unit being controlled by the error signal (PD) output from the phase comparator, and a first mirror circuit (117) for maintaining, at a value in accordance with the voltage signal (D) supplied from the D/A converter, a current (I) flowing into the first switching unit from the low-pass filter through the output terminal (116) when the first switching unit turns on.

The charge pump may also include a second switching unit (Q6) connected between the output terminal (116) of the charge pump and a terminal of the second voltage (VDD), conductivity of the second switching unit being controlled by the error signal (PU) output from the phase comparator, and a second mirror circuit (118) for maintaining, at a value in accordance with the voltage signal (D) supplied from the D/A converter, a current (I) flowing into the low-pass filter from the second switching unit through the output terminal (116) when the second switching unit turns on.

### BRIEF DESCRIPTION OF THE DRAWINGS

FIG. 1 is a block diagram of a PLL device according to a first embodiment of the invention;

FIG. 2 is a circuit diagram of a charge pump used for the PLL device according to the first embodiment of the invention;

FIG. 3 is a timing diagram of signals in various parts of the PLL device according to the first embodiment of the invention;

FIG. 4 is a block diagram of a PLL device according to a second embodiment of the invention;

FIG. 5 is a circuit diagram of a phase comparator used for the PLL device according to the second embodiment of the invention;

FIG. 6 is a view showing a characteristic of the phase comparator used for the PLL device according to the second embodiment of the invention;

FIG. 7 is a block diagram of a PLL device according to a third embodiment of the invention;

FIG. 8 is a circuit diagram of a phase comparator used for the PLL device according to the third embodiment of the invention;

FIG. 9 is a view showing a characteristic of the phase comparator used for the PLL device according to the third embodiment of the invention;

FIG. 10 is a block diagram of a PLL device according to a fourth embodiment of the invention;

FIG. 11 is a circuit diagram of a phase detector used for the PLL device according to the fourth embodiment of the invention;

FIG. 12 is a timing diagram of signals in various parts of the PLL device according to the fourth embodiment of the invention; and

FIG. 13 is a circuit diagram of a PLL device according to a fifth embodiment of the invention.

### BEST MODES OF PRACTICING THE INVENTION

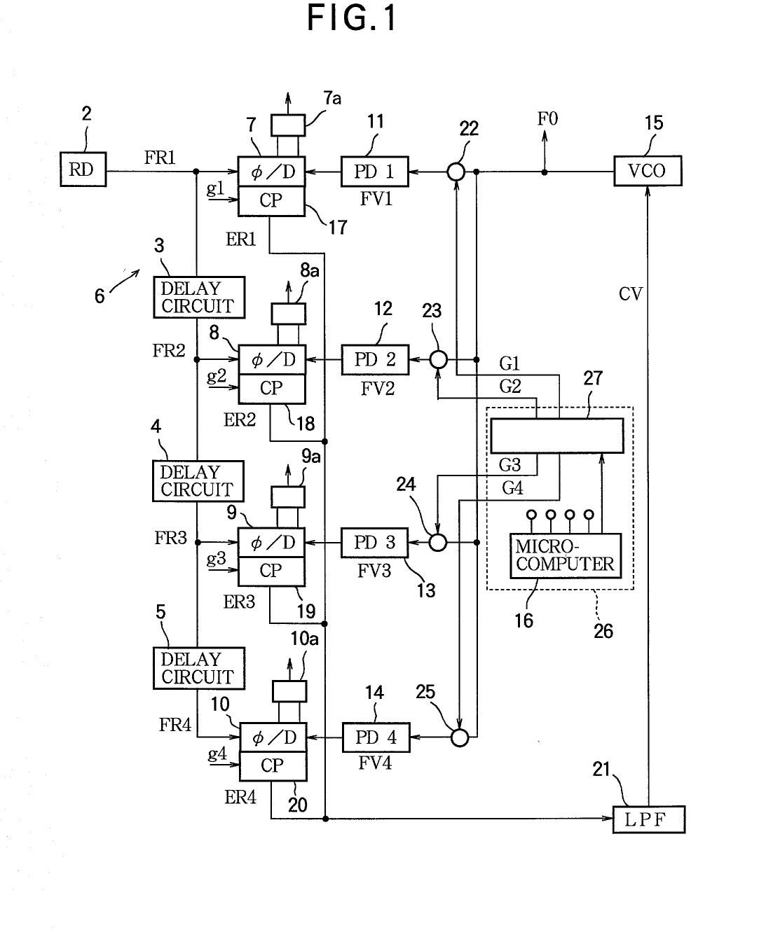

A PLL device according to a first embodiment of the invention will be explained below with reference to a block diagram of FIG. 1. In FIG. 1, a reference oscillator 2 outputs a reference signal FR1. Delay circuits 3, 4, 5 produce a plurality of reference signals FR2, FR3, FR4 having mutually differing phases in response to the reference signal FR1. This reference oscillator 2 and the delay circuits 3, 4, 5 constitute a (reference signal) generating means 6.

To be more specific, the reference signal FR1 is input into a phase comparator 7. The delay circuit 3 delays the reference signal FR1 by ¼ period, and outputs it as the reference signal FR2 to a phase comparator 8. The delay circuit 4 delays the reference signal FR1 by ½ period, and outputs it as the reference signal FR3 to a phase comparator 9. The delay circuit 5 delays the reference signal FR1 by ¾ period, and outputs it as the reference signal FR4 to a phase comparator 10.

Variable frequency dividers 11, 12, 13, 14 whose inputs are connected to the output of a voltage-controlled oscillator 15 divide the frequency of an output signal FO by an integer frequency-division ratio to produce feedback signals FV1, FV2, FV3, FV4.

The phase comparator 7 compares the phase and frequency of the output (the feedback signal FV1) of the variable frequency divider 11 with the phase and frequency of the reference signal FR1. The phase comparator 7 outputs, as a result of the comparison, a pump-up signal and a pump-down signal to two output terminals. A detector 7a with an AND gate etc. receiving the pump-up signal and the pump-down signal delivers an output signal (a detection signal) of the AND gate to a microcomputer 16. A locked state is detected by the detector 7a. The pump-up signal and the pump-down signal are supplied to a charge pump 17 as well to produce an error signal ER1.

Likewise, the phase comparator 8 compares the phase and frequency of the feedback signal FV2 from the variable frequency divider 12 with the phase and frequency of the reference signal FR2. The phase comparator 8 outputs, as a result of the comparison, a pump-up signal and a pump-down signal to a detector 8a. The detector 8a delivers an AND of these signals as a detection signal of the locked state to the microcomputer 16. These signals are also input into a charge pump 18 to output an error signal ER2.

The phase comparator 9 compares the phase and frequency of the feedback signal FV3 from the variable frequency divider 13 with the phase and frequency of the reference signal FR3. The phase comparator 9 outputs, as a result of the comparison, a pump-up signal and a pump-down signal to a detector 9a. The detector 9a delivers an AND of these signals as a detection signal of the locked state to the microcomputer 16. These signals are also input into a charge pump 19 to output an error signal ER3.

The phase comparator 10 compares the phase and frequency of the feedback signal FV4 from the variable frequency divider 14 with the phase and frequency of the reference signal FR4. The phase comparator 10 outputs, as a result of the comparison, a pump-up signal and a pump-down signal to a detector 10a. The detector 10a delivers an AND of these signals as a detection signal of the locked state to the microcomputer 16. These signals are also input into a charge pump 20 to output an error signal ER4.

In this way, the phase comparators 7, 8, 9, 10 compare phases between the reference signals FR1, FR2, FR3, FR4 and the feedback signals FV1, FV2, FV3, FV4, and output the error signals ER1, ER2, ER3, ER4 as results of the comparisons.

A Low-pass filter 21 delivers a control voltage CV to the voltage-controlled oscillator 15 in response to the error signals ER1, ER2, ER3, ER4 from the phase comparators 7, 8, 9, 10. The voltage-controlled oscillator 15 generates the output signal FO in response to the control voltage CV.

The gate 22 is disposed between the output of the voltage-controlled oscillator 15 and the input of the variable frequency divider 11. The gate 23is disposed between the output of the voltage-controlled oscillator 15 and the input of the variable frequency divider 12. The gate 24is disposed between the output of the voltage-controlled oscillator 15 and the input of the variable frequency divider 13. The gate 25 is disposed between the output of the voltage-controlled oscillator 15 and the input of the variable frequency divider 14.

A control unit 26 is constituted by the microcomputer 16 receiving the detection signals from the detectors 7a, 8a, 9a, 10a, a gate control circuit 27 and so on. The gate control circuit 27 comprised of logic circuits generates control signals G1, G2, G3, G4 and control signals g1, g2, g3, g4 in response to signals from the microcomputer 16 and the reference signals FR1 to FR4.

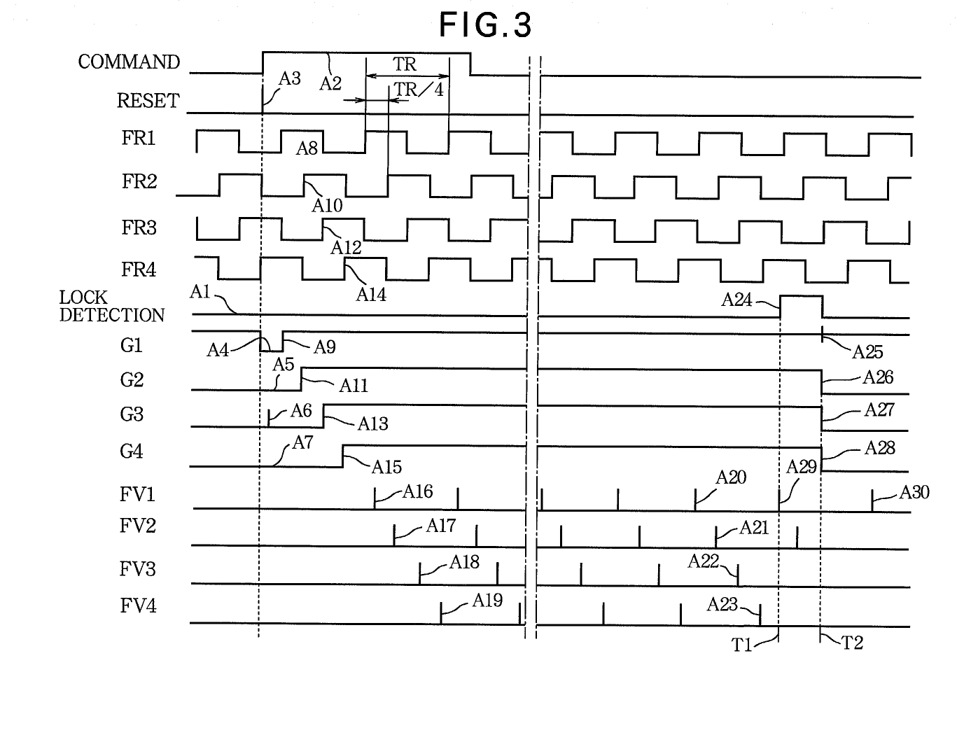

The control signal G1 is supplied to the gate 22, the control signal G2 is supplied to the gate 23, the control signal G3 is supplied to the gate 24, and the control signal G4 is supplied to the gate 25. Likewise, the control signals g1, g2, g3, g4 are supplied from the gate control circuit 27 to the charge pumps 17, 18, 19, 20. The gate control circuit 27 may have any configuration if it can generate the above-described control signals in accordance with the timings shown in a timing diagram in FIG. 3. For example, it may have the same configuration as Japanese Patent Application No. 11-215251 filed by the present applicant. So, detailed explanation of the internal structure of the control circuit 27 is omitted.

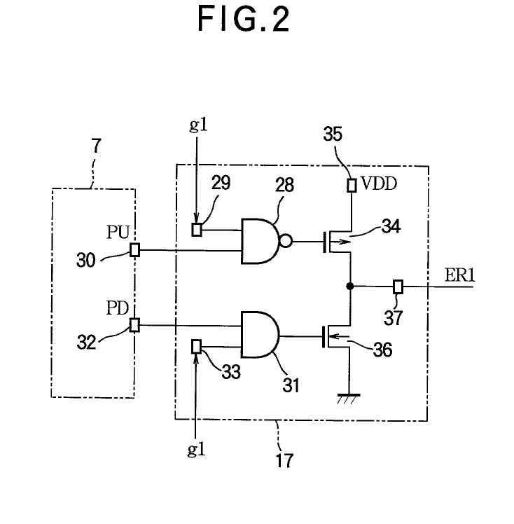

Next, the charge pump 17 will be explained with reference to a circuit diagram shown in FIG. 2. In FIG. 2, the charge pump 17 is disposed after the phase comparator 7. In the charge pump 17, one input of a NAND gate 28 is connected to a first input terminal 29 to receive the control signal g1. The other input of the NAND gate 28 is connected to a first output terminal 30 of the phase comparator 7 to receive a pump-up signal PU.

One input of an AND gate 31 is connected to a second output terminal 32 of the phase comparator 7 to receive a pump-down signal PD. The other input of the AND gate 31 is connected to a second input terminal 33 to receive the control signal g1.

A first transistor 34, which may be a P-channel MOS FET, has a drain connected to a third input terminal 35 to be supplied with a source voltage VDD. A gate of the first transistor 34 is connected to the output of the NAND gate 28.

A second transistor 36, which may be an n-channel MOS FET, has a gate connected to the output of the AND gate 31. The second transistor 36 has a source to be grounded, and a drain connected to a source of the first transistor 34.

A node of the source of the first transistor 34 and the drain of the second transistor 36 is connected to an output terminal 37 so that the error signal ER1 is delivered through the output terminal 37. The charge pump 17 is constituted by the above-explained components. The charge pumps 18, 19, 20 have the same configuration as the charge pump 17. This PLL device is constituted by the above-explained components.

The operation of this PLL device will now be explained with reference to FIG. 1 to FIG. 3. FIG. 3 is a timing diagram of various signals in the PLL device 1 according to this embodiment. In these FIGS. shown is a case where a user selects, for example, a frequency of 300 kHz by a channel selection key, presses a start key to output the output signal FO of 300 kHz, and thereafter, changes the frequency to, for example, 1500 kHz by the channel selection key.

When the output signal FO of 300 kHz is first delivered (the output signal FO is locked at that time), either one of the detectors 7a, 8a, 9a, 10a outputs the detection signal. However, the detection signal is at an L level (Low level) at time A1 (see FIG. 3) since this signal is a one-shot pulse signal.

Suppose that the user manipulates the channel selection key to change from 300 kHz to 1500 kHz. In accordance with this change, a frequency alteration command is input into the gate control circuit 27. Since this command is formed as a one-shot type at this time, it is a H-level signal for a short period of time, and goes low afterward (see A2 in FIG. 3).

Then, the control signals G1 and g1 output from the gate control circuit 27 change from the H-level (High level) signals to the L-level signals, and kept at the L level until a predetermined time elapses after this change (see A4 in FIG. 3). Likewise, the control signals G2, g2, G3, g3, G4, g4 are kept at the L level for a predetermined time (see A5, A6, A7 in FIG. 3) after a reset signal is output at the rise of the command signal (see A3 in FIG. 3). The gates 22, 23, 24, 25 are closed then, so delivery of the output signal FO to the variable frequency dividers 11, 12, 13, 14 is stopped. The frequency dividers 11, 12, 13, 14 stop their counting operations and set their count values at a predetermined value (0, for example).

Since the control signals g1 to g4 are at the L level at this time and the charge pumps 17 to 20 are therefore in a high-impedance state, deliveries of the error signals ER1, ER2, ER3, ER4 to the low-pass filter 21 are stopped. In this way, the control unit 26 resets the variable frequency dividers 11 to 14 before they begin frequency division operations.

The control signal G1 from the gate control circuit 27 rises (A9) following the rise (A8) of the reference signal FR1, so the gate 22 opens, the output signal FO is delivered to the variable frequency divider 11, and the variable frequency divider 11 begins frequency division operation. The charge pump 17 leaves the high-impedance state following the rise (A9) of the control signal g1, and the phase comparator 7 compares phases between the output signal FO divided by the variable frequency divider 11, or the feedback signal FV1 and the reference signal FR1 to output the error signal ER1 (see A16 in FIG. 3).

Likewise, the control signal G2 rises (A11) following the rise (A10) of the reference signal FR2, so the gate 23 opens, the output signal FO is delivered to the variable frequency divider 12, and the variable frequency divider 12 begins frequency division operation. The charge pump 18 leaves the high-impedance state following the rise (A11) of the control signal g2, and the phase comparator 8 compares phases between the output signal FO divided by the variable frequency divider 12, or the feedback signal FV2 and the reference signal FR2 to output the error signal ER2 (see A17 in FIG. 3).

The control signal G3 rises (A13) following the rise (A12) of the reference signal FR3, so the gate 24 opens, the output signal FO is delivered to the variable frequency divider 13, and the variable frequency divider 13 begins frequency division operation. The charge pump 19 leaves the high-impedance state following the rise (A13) of the control signal g3, and the phase comparator 9 compares phases between the feedback signal FV3 and the reference signal FR3 to output the error signal ER3 (see A18 in FIG. 3).

Furthermore, the control signal G4 rises (A15) following the rise (A14) of the reference signal FR4, so the gate 25 opens, the output signal FO is delivered to the variable frequency divider 14, and the variable frequency divider 14 begins frequency division operation. The charge pump 20 leaves the high-impedance state following the rise (A15) of the control signal g4, and the phase comparator 10 compares phases between the feedback signal FV4 and the reference signal FR4 to output the error signal ER4 (see A19 in FIG. 3).

In this way, the control unit 26 causes the variable frequency dividers 11 to 14 to start frequency division operations in synchronization with the phases of the reference signals FR1 to FR4 (for example, the rises A8, A10, A12, A14 and so on). To be more specific, the gate control circuit 27 of the control unit 26 causes the gates 22 to 25 to open by the control signals G1 to G4 in synchronization with the phases of the reference signals FR1 to FR4 to have the charge pumps 17 to 20 leave the high-impedance state (generate output signals).

As described above, the reference oscillator 2 generates the reference signal FR1 having the reference frequency FR (period TR=1/FR).The delay circuits 3, 4, 5 produce the reference signals FR2, FR3, FR4 by delaying the reference signal FR1 in steps of ¼ period (TR/4) sequentially.

The times at which the variable frequency dividers 11, 12, 13, 14 begin frequency division operations are in synchronization with the phases of the reference signals FR1, FR2, FR3, FR4. Accordingly, the starting times for the frequency division operations are delayed in steps of about TR/4 sequentially, and the phase comparison timings in the phase comparators 7, 8, 9, 10 are delayed in steps of about TR/4 sequentially as well.

By having the variable frequency dividers 11 to 14 start the frequency division operations in synchronization with the phases of the reference signals FR1 to FR4 as described above, the phase comparison timings in the phase comparators 7, 8, 9, 10 are evenly spaced, which enables correct phase comparisons.

As described above, the reference signals FR1 to FR4 have different phases (they are out of phase with each other by π/2 in this explanation), and phase comparisons are performed for each of the reference signals FR1 to FR4. As a result, phase comparisons are performed multiple times (four times A16, A17, A18, A19 in this explanation) during one period (TR) of the reference signal FR1, and accordingly the lock-up time is shortened to approximately ¼ of the conventional time.

As time elapses and the above phase comparisons are repeated (see A20, A21, A22, A23 in FIG. 3), the output signal FO reaches (locks onto) the set frequency. Then, one of the detectors 7a, 8a, 9a, 10a connected to the phase comparators 7, 8, 9, 10 outputs a detection signal to the microcomputer 16. Suppose that the detector 7a has detected the lock. The microcomputer 16 outputs a lock detection signal to the gate control circuit 27 (see A24 in FIG. 3; the lock detection signal is of the one-shot type).

In this way, when either one of the detectors 7a, 8a, 9a, 10a detects the locked state from the outputs of the phase comparators 7, 8, 9, 10, the control unit 26 switches the control signals g2, g3, g4 from the H level to the L level. As a result, the charge pumps 18, 19, 20 go into the high-impedance state (see FIG. 2). Accordingly, the phase comparators 8, 9, 10 do not generate output signals (the phase comparators 8, 9, 10 do not deliver output signals to the low-pass filter 21).

Since the control signal g1 remains at the H level at this time, the charge pump 17 is in an enabled state (a state out of high-impedance). As a result, the output signal of the phase comparator 7 continues delivered as the error signal ER1 to the low-pass filter 21 through the charge pump 17.

To summarize the material above, when one of the detectors 7a, 8a, 9a, 10a detects a locked state or a nearly locked state, the control unit 26 keeps on outputting the control signal g1 at the H level, while switches the control signals g2, g3, g4 to the L level.

As a result, the charge pumps 18 to 20 go into the high-impedance state, and accordingly the phase comparators 8 to 10 connected to the charge pumps 18 to 20 do not generate output signals. In this state, the phase comparator 7 alone generates an output signal. Thus, the number of the comparator stages of a plurality of the phase comparators 7 to 10 in use is reduced from four to one.

In other words, to reduce the number of the comparator stages in use of a plurality of the phase comparators 7 to 10, the charge pumps 18 to 20 connected to the phase comparators 8 to 10 to be out of use are set in the high-impedance state. At this time (see the time T1 in FIG. 3), the control signals G1 to G4 remain at the H level, so the variable frequency dividers 11 to 14 keep on frequency division operations to continue outputting the feedback signals FV1 to FV4. The control unit 26 switches the control signals G2, G3, G4 from the H level to the L level (see A26, A27, and A28 in FIG. 3) after a lapse of a predetermined time (the time T2 in FIG. 3) after the phase comparators 8 to 10 stop generating output signals (the time T1 in FIG. 3). Only the control signal G1 is maintained at the H level (see A25 in FIG. 3).

To summarize the material above, the variable frequency dividers 12 to 14 connected to the phase comparators 8 to 10 out of use stop frequency division operations (see A26, A27, A28 in FIG. 3) after a lapse of a predetermined time (the time T2) after the phase comparators 8 to 10 to be out of use stop generating output signals (the time T1). By stopping the variable frequency dividers 12 to 14 after lock, electric power consumption can be reduced.

Since the control signal G1 is kept at the H level, the gate 22 continues to be in the open state, and the variable frequency divider 11 keeps on performing frequency division operation. The phase comparator 7 compares phases between the feedback signal FV1 output from the variable frequency divider 11 and the reference signal FR1 (see A29, A30 in FIG. 3).

The charge pump 17 controlled by the control signal g1 is in the enabled state at this time, the charge pump 17 outputs the error signal ER1 to the low-pass filter 21. The low-pass filter 21 outputs the control signal CV to the voltage-controlled oscillator 15, and the voltage-controlled oscillator 15 keeps on outputting the output signal FO that has reached the setting frequency. That is, the phase comparator 7 after lock keeps on outputting the error signal.

The above material is summarized as follows. Suppose that at least one of the detectors 7a, 8a, 9a, 10a connected to the phase comparators 7, 8, 9, 10, (detector 7a, for example) has detected the lock. The detector 7a outputs the lock detection signal to the microcomputer 16 of the control unit 30.

The control unit 26 allows the phase comparator that has detected the lock or any specific phase comparator 7 to keep on delivering an output (see A25 in FIG. 3), and disables the outputs of the other phase comparators 8, 9, 10 (see A26, A27, A28 in FIG. 2), or prohibits them from generating output signals.

The control unit 26 allows only the variable frequency divider 11 connected to the phase comparator 7 that keeps on delivering an output to continue performing frequency division operation, and after a lapse of a predetermined time, stops the other variable frequency dividers 12, 13, 14 from performing frequency division operations.

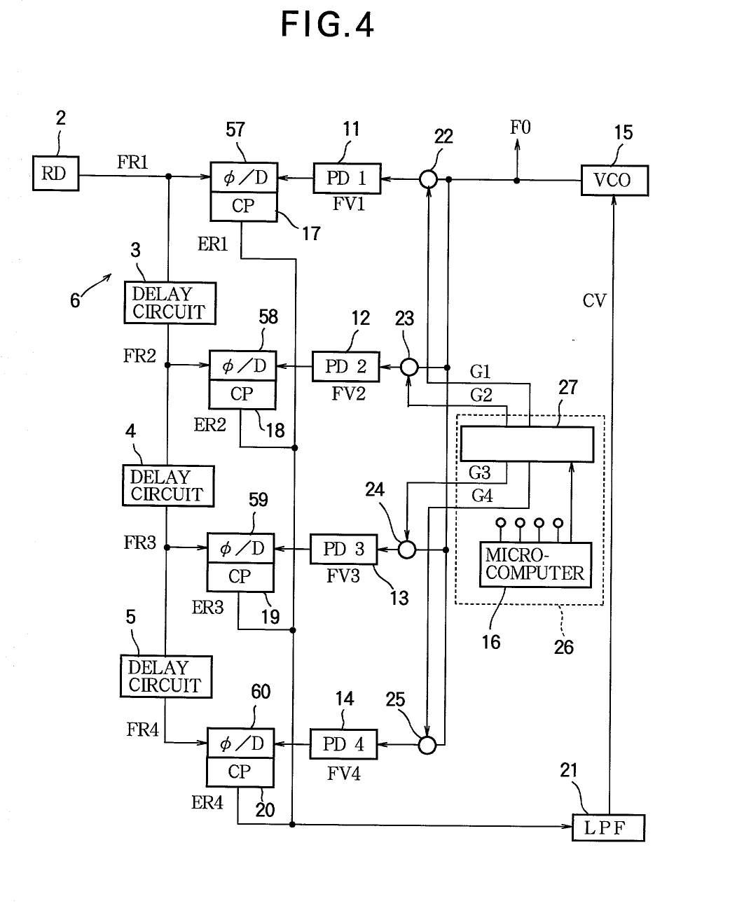

A PLL device according to a second embodiment of the invention will be explained with reference to a block diagram of FIG. 4. In FIG. 4, the elements that are the same as those in FIG. 1 are given the same reference characters, and explanation thereof will be omitted.

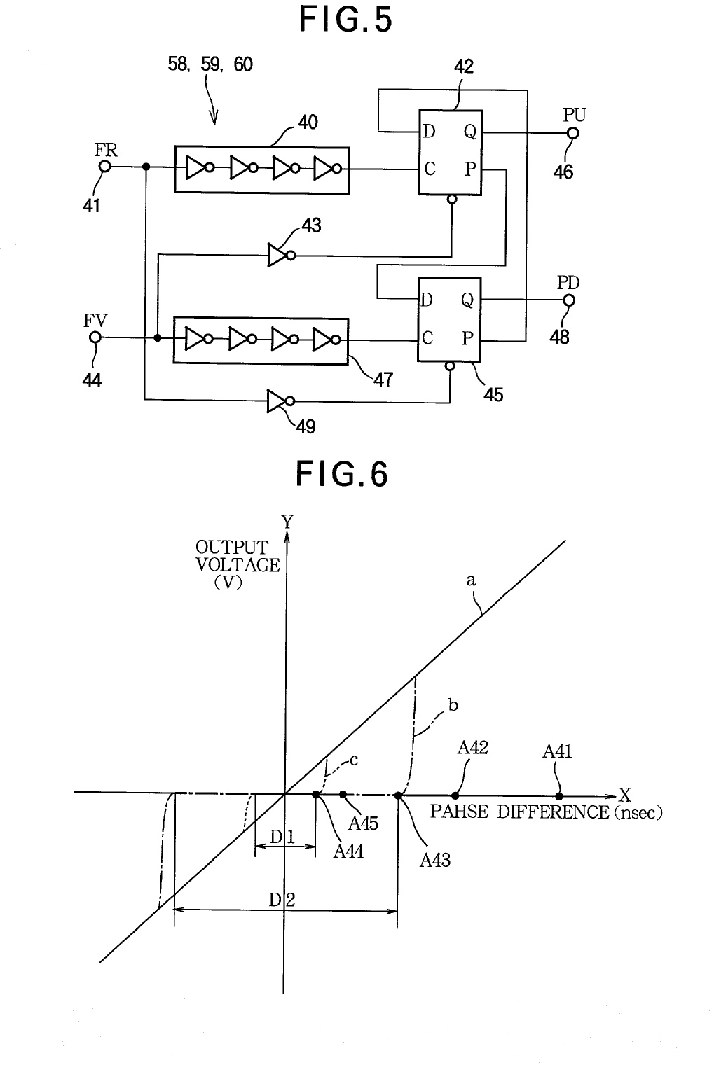

Phase comparators 57 to 60 will be explained in detail with reference to FIG. 4 to FIG. 6. The phase comparators 57 to 60 are divided into at least two groups. For example, the phase comparator 57 is a first phase comparator, and the phase comparators 58, 59, 60 are second phase comparators. FIG. 5 is a circuit diagram of the second phase comparator, and FIG. 6 is a view showing characteristics of the phase comparators 57 to 60.

The second phase comparators 58, 59, 60 will be explained with reference to the diagram of FIG. 5. In FIG. 5, a first delay circuit 40 is constituted by, for example, a series circuit of a plurality of inverters. The first delay circuit 40 has an input connected to a first input terminal 41, and an output connected to a clock terminal C of a flip-flop 42.

A reset terminal of the flip-flop 42 is connected to a second input terminal 44 through an inverter 43. An input terminal D of the flip-flop 42 is connected to an inverted-output terminal P of a flip-flop 45. An output terminal Q of the flip-flop 42 is connected to a first output terminal 46, and an inverted-output terminal P of the flip-flop 42 is connected to an input terminal D of the flip-flop 45.

A second delay circuit 47 which may be constituted by a series circuit of a plurality of inverters has an input connected to the second input terminal 44 and an output connected to a clock terminal C of the flip-flop 45. The flip-flop 45 has an output terminal Q connected to a second output terminal 48, and a reset terminal connected to the first input terminal 41 through an inverter 49. The second phase comparator 58, 59, 60 are constituted by these components.

In the second phase comparator 58, the first input terminal 41 is supplied with the reference signal FR2, and the second input terminal 44 is supplied with the feedback signal FV2. From the first output terminal 46 output is the pump-up signal PU. From the second output terminal 48 output is the pump-down signal PD.

In this configuration, when a pulse as the reference signal FR2 enters the first input terminal 41, this pulse is delayed by the first delay circuit 40. When a pulse as the feedback signal FV2 enters the second input terminal 44, the phase of this pulse is compared with the phase of the above delayed pulse. As a result, the pump-up signal PU or the pump-down signal PD is output from the first output terminal 46 or the second output terminal 48.

In a case where the first and second delay circuits are not provided, when the feedback signal FV2 lags behind the reference signal FR by a certain time, there appears, in the first output terminal 46, a pump-up signal which falls from the H level to the L level following the fall of the pulse of the reference signal FR2 and returns to the H level following the fall of the subsequent pulse of the feedback signal FV2. On the other hand, when the feedback signal FV2 leads the reference signal FR by a certain time, there appears, in the second output terminal 48, a pump-down signal which falls from the H level to the L level following the fall of the pulse of the feedback signal FV2 and returns to the H level following the fall of the subsequent pulse of the reference signal FR2. However, if a delay time of the first and the second delay circuits is larger than the time lag (phase difference) between the feedback signal and the reference signal, the pump-up signal and the pump-down signal do not appear. Accordingly, by delaying the phase comparison timing by use of the first delay circuit 40 and the second delay circuit 47, the output voltage becomes zero even when the phase difference between the reference signal FR2 and the feedback signal FV2 is relatively large.

In FIG. 6, the horizontal axis represents the phase difference between the reference signal FR and the feedback signal FV, and the vertical axis represents the output voltage (the pump-up signal PU, the pump-down signal). A characteristic of an ideal phase comparator with no dead zone is shown by a. A characteristic of a phase comparator with a large dead zone D2 is shown by b. A characteristic of a phase comparator with a small dead zone D1 is, shown by c.

As described above with reference to FIG. 5, the output voltages of the second phase comparators 58, 59, 60 become zero even when the phase difference between the reference signal FR and the feedback signal FV is relatively large since they are provided with the first delay circuit 40 and the second delay circuit 47. So, the second phase comparators 58, 59, 60 have the characteristic b exhibiting the large dead zone D2.

The first phase comparator 57 may be the same as the second phase comparators 58, 59, 60 except that it has not the first delay circuit 40 and the second delay circuit 47. Therefore, the timing for comparing phases between the reference signal FR1 and the feedback signal FV1 is not altered, and the output voltage becomes zero when the phase difference is relatively small. So, the first phase comparator 57 has the characteristic c exhibiting the small dead zone D1.

As described above, in this PLL device1, the dead zone of the first phase comparator is different from that of the second phase comparator. To be more specific, the dead zone D1 of the first phase comparator 57 is made small, and the dead zone D2 of the second phase comparators 58, 59, 60 is made large. The PLL device of this embodiment is constituted by the above-described components.

Next, the operation of this PLL device will be explained with reference to FIG. 4 to FIG. 6. In these FIGS., when a user presses a start button, a start signal enters the control unit 26.

The control unit 26 allows supply of the source voltage to the components shown in FIG. 4 in response to the start signal. The reference oscillator 2 outputs the reference signals FR1 to FR4. The control signals G1 to G4 are still at the L level at this time. The gates 22 to 25 are closed, and the variable frequency dividers 11 to 14 do not perform frequency division operations.

The control unit 26 switches the control signal G1 to the H level, and outputs an H-level signal to the gate 22 after a lapse of a predetermined time after reception of the start signal. As a result, the variable frequency divider 11 begins frequency division operation to supply the phase comparator 57 with the feedback signal FV1 resulting from dividing the feedback signal FV1 by a set frequency-division ratio.

When the reference signal FR1 rises after a lapse of time, the phase comparator 57 compares phases between the reference signal FR1 and the feedback signal FV1 and outputs the error signal ER1 to the low-pass filter 21 through the charge pump 17.

After a further lapse of time, the control unit 26 switches the control signal G2 to the H level, and opens the gate 23. The gate 22 is left open at this time.

The variable frequency divider 12 begins frequency division operation at this time, and outputs the feedback signal FV2 to the phase comparator 58. When the reference signal FR2 rises after a lapse of time, the phase comparator 58 compares phases between the reference signal FR2 and the feedback signal FV2, and outputs the error signal ER2 to the low-pass- filter 21 through the charge pump 18.

After a further lapse of time, the control unit 26 switches the control signal G3 to the H level, and opens the gate 24. The gate 23 is left open at this time.

The variable frequency divider 13 begins frequency division operation at this time, and outputs the feedback signal FV3 to the phase comparator 59. When the reference signal FR3 rises after a lapse of time, the phase comparator 59 compares phases between the reference signal FR3 and the feedback signal FV3, and outputs the error signal ER3 to the low-pass filter 21 through the charge pump 19.

After a further lapse of time, the control unit 26 switches the control signal G4 to the H level, and opens the gate 25. The gate 24 is left open at this time.

The variable frequency divider 14 begins frequency division operation at this time, and outputs the feedback signal FV4 to the phase comparator 60. When the reference signal FR4 rises after a lapse of time, the phase comparator 60 compares phases between the reference signal FR4 and the feedback signal FV4, and outputs the error signal ER4 to the low-pass filter 21 through the charge pump 20.

To summarize the material above, the control unit 26 causes the variable frequency dividers 11 to 14 to start frequency division operations in synchronization with the phases of the reference signals FR1 to FR4. The first phase comparator 57 and the second phase comparators 58, 59, 60 each compare phases between the reference signals FR1 to FR4 and the feedback signals FV1 to FV4. As results, the phase comparators 57 to 60 output the error signals ER1 to ER4 to the low-pass filter 21 through the charge pumps 17 to 20 respectively.

The low-pass filter 21 outputs the control voltage CV to the voltage-controlled oscillator 15 in response to the error signals ER1 to ER4. The voltage-controlled oscillator 15 generates the output signal FO in response to the control voltage CV. Such a state is represented by a point A41 (see FIG. 6). The phase difference between the reference signal FR and the feedback signal FV is large in this state.

As described above, the reference oscillator 2 generates the reference signal FR1 having the reference frequency FR (period TR=1/FR). The reference signals FR2, FR3, FR4 are produced by delaying the reference signal FR1 in steps of ¼ period (TR/4) sequentially.

The times at which the variable frequency dividers 11, 12, 13, 14 begin frequency division operations are synchronized with the phases of the reference signals FR1, FR2, FR3, FR4. Accordingly, the starting times for the frequency division operations are delayed in steps of about TR/4 sequentially, and the phase comparison timings in the phase comparators 57, 58, 59, 60 are delayed in steps of about TR/4 sequentially as well.

By having the variable frequency dividers 11 to 14 start the frequency division operations in synchronization with the phases of the reference signals FR1 to FR4 as described above, the phase comparison timings in the phase comparators 57, 58, 59, 60 are evenly spaced, which enables correct phase comparisons.

The reference signals FR1 to FR4 have different phases (they are out of phase with each other by π/2 in this explanation) and phase comparisons are performed for each of the reference signals FR1 to FR4. As a result, phase comparisons are performed multiple times during one period (TR) of the reference signal FR1, and accordingly the lock-up time is shortened to approximately ¼ of the conventional time.

As time elapses and the above phase comparisons are repeated, the phase of the feedback signal FV resulting from dividing the frequency of the output signal FO approaches the reference signal FR (see the point A42 in FIG. 6). If this state is referred to as “un-locked state”, the first phase comparator 57 and the second phase comparator 58, 59, 60 operate simultaneously in four stages to output the error signals ER1 to ER4 to the low-pass filter 21 through the charge pumps 17 to 20 in this unlocked state.

After a further lapse of time, through repetition of phase comparisons, the phase difference between the reference signal FR and the feedback signal FV reaches the point A43 (see FIG. 6). At this time, as shown in FIG. 6, the outputs of the second phase comparators 58, 59, 60 become zero, so the error signals ER2 to ER4 output from the charge pumps 18 to 20 connected to the second phase comparator 58, 59, 60 become zero.

If the point A43 is referred to as “nearly-locked state”, the first phase comparator 57 alone delivers an output in this nearly-locked state. As described above, the number of the phase comparator output stages is four at the point A41 or A42 (where the first phase comparator 57 and the second phase comparators 58, 59, 60 deliver outputs), while it becomes one when the point A43 is reached (where the first phase comparator 57 alone delivers an output).

After a further lapse of time, through repetition of phase comparisons, the phase difference between the reference signal FR1 and the feedback signal FV1 reaches the point A44. At this time, the output of the first phase comparator 57 becomes zero, so the error signal ER1 output from the charge pump 17 becomes zero (see FIG. 6). By setting the point A44 smaller than the point A45 at which the PLL device 1 enters the “locked state”, this PLL device can be maintained within the locked state by the output of the first phase comparator 57.

To summarize the material above, the span of the dead zone D1 of the first phase comparator 57 is made different from the span of the dead zone D2 of the second phase comparators 58, 59, 60. As a result, it is unnecessary to have means (a gate or the like previously disposed after the phase comparator) for switching externally the phase comparators 57 to 60.

That is because when the phase difference between the reference signal FR and the feedback signal FV becomes small through repetition of phase comparisons by the first phase comparator 57 and the second phase comparators 58, 59, 60, the outputs of the phase comparators having the larger dead zone (the second phase comparators 58, 59, 60) become zero.

As a result, the number of the output stages of the phase comparators 57 to 60 is switched from four to one at the point A43 in FIG. 6. Thus, the number of the output stages is switched to one automatically without any external switching means due to the characteristic in itself (the dead zone D2 being large) of the second phase comparators 58, 59, 60.

Furthermore, in FIG. 6, the phase comparators 57 to 60 are caused to deliver outputs in four stages over a period from the point A41 to a point immediately before the point A43 to increase the number of phase comparisons during one period of the reference signal (four times the conventional number) and move up the start-up (reduction of the lock-up time). By switching the number of the output stages of the phase comparators 57 to 60 to one when the nearly-locked state is reached (the point A43 in FIG. 6), it is possible to avoid interference between the output of the phase comparator 57 and the outputs of the other phase comparators (the second phase comparator 58 to 60, for example).

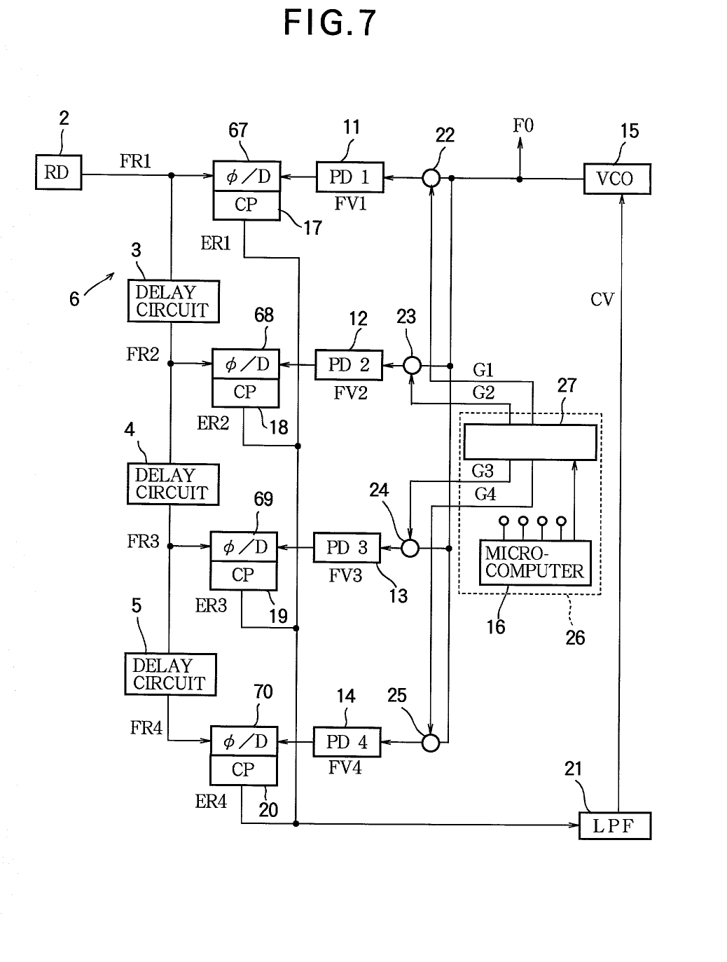

A PLL device 1 according to a third embodiment of the invention will be explained with reference to FIG. 7. In FIG. 7, the elements that are the same as those in FIG. 1 are given the same reference characters, and explanation thereof will be omitted.

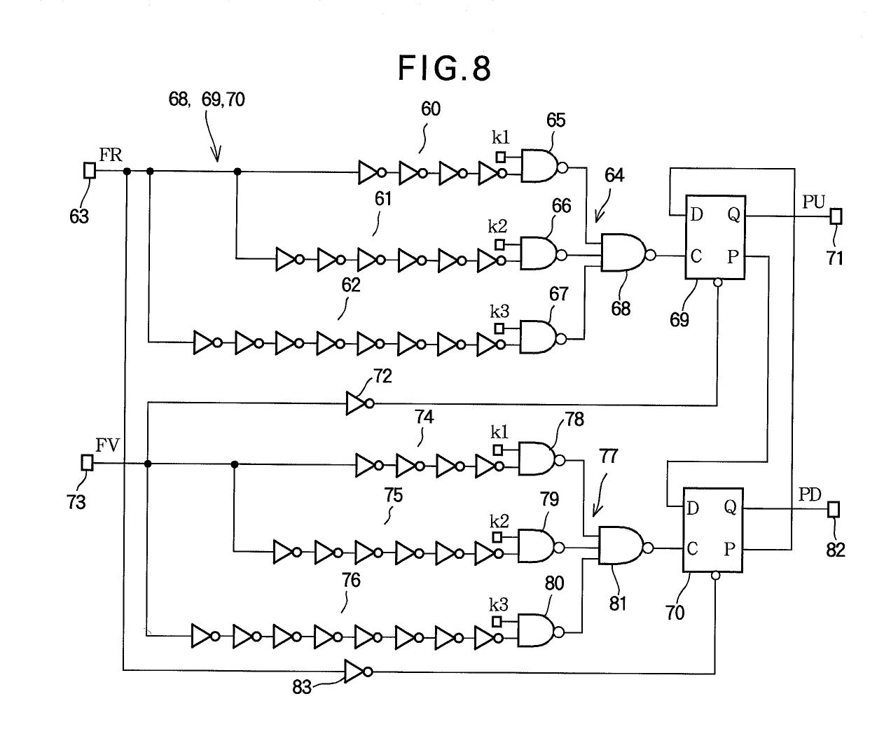

Phase comparators 67 to 70 will be explained in- detail with reference to FIG. 7 and FIG. 8. FIG. 7 is a block diagram of the phase comparators 68, 69, 70. In these FIGS., for example, a delay circuit 60 is constituted by four inverters connected in series, a delay circuit 61 is constituted by six inverters connected in series, and a delay circuit 62 is constituted by eight inverters connected in series.

The delay circuits 60, 61, 62 constituted by different numbers of inverters have different delay times.

One end of each of the delay circuits 60, 61, 62 is coupled to a common input. To be more specific,the one end is connected to a first input terminal 63 which receives a reference signal FR.

The other end of each of the delay circuits 60, 61, 62 is connected to a selection circuit 64. The selection circuit 64 is constituted by, for example, NAND gates 65, 66, 67, 68.

One input of the NAND gate 65 is connected to the other end of the delay circuit 60, and the other input of the NAND gate 65 is connected to a control unit 26 to receive a control signal k1. An output of the NAND gate 65 is connected to one input of the NAND gate 68.

One input of the NAND gate 66 is connected to the other end of the delay circuit 61, and the other input of the NAND gate 66 is connected to the control unit 26 to receive a control signal k2. An output of the NAND gate 66 is connected to one input of the NAND gate 68.

One input of the NAND gate 67 is connected to the other end of the delay circuit 62, and the other input of the NAND gate 67 is connected to the control unit 26 to receive a control signal k3. An output of the NAND gate 67 is connected to one input of the NAND gate 68.

A clock terminal C of a flip-flop 69 is connected to an output of the NAND gate 68. An input terminal D of the flip-flop 69 is connected to an inverted-output terminal P of a flip-flop 70. An output terminal Q of the flip-flop 69 is connected to a first output terminal 71 to output a pump-up signal PU.

An inverted-output terminal P of the flip-flop 69 is connected to an input terminal D of the flip-flop 70. A reset terminal of the flip-flop 69 is connected to a second input terminal 73 through an inverter 72. The second input terminal 73 is supplied with a feedback signal FV.

For example, a delay circuit 74 is constituted by four inverters connected in series, a delay circuit 75 is constituted by six inverters connected in series, and a delay circuit 76 is constituted by eight inverters connected in series.

As explained above, the delay circuits 74, 75, 76 are constituted by different numbers of inverters to have different delay times. One end of each of the delay circuits 74, 75, 76 is coupled to a common input. To be more specific, the one end is connected to a second input terminal 73 which receives the feedback signal FV.

The other end of each of the delay circuits 74, 75, 76 is connected to a selection circuit 77. The selection circuit 77 is constituted by, for example, NAND gates 78, 79, 80, 81.

One input of the NAND gate 78 is connected to the other end of the delay circuit 74, and the other input of the NAND gate 78 is connected to the control unit 26 to receive the control signal k1. An output of the NAND gate 78 is connected to one input of the NAND gate 81.

One input of the NAND gate 79 is connected to the other end of the delay circuit 75, and the other input of the NAND gate 79 is connected to the control unit 26 to receive the control signal k2. An output of the NAND gate 79 is connected to one input of the NAND gate 81.

One input of the NAND gate 80 is connected to the other end of the delay circuit 76, and the other input of the NAND gate 80 is connected to the control unit 26 to receive the control signal k3. An output of the NAND gate 80 is connected to one input of the NAND gate 81.

A clock terminal C of the flip-flop 70 is connected to an output of the NAND gate 81. The input terminal D of the flip-flop 70 is connected to the inverted-output terminal P of the flip-flop 69. An output terminal Q of the flip-flop 70 is connected to a second output terminal 82 to deliver a pump-down signal PD.

The inverted-output terminal P of the flip-flop 70 is connected to the input terminal D of the flip-flop 69. A reset terminal of the flip-flop 70 is connected to the first input terminal 63 through an inverter 83. The second input terminal 73 is supplied with the feedback signal FV.

As explained above, a plurality of the delay circuits 60 to 62 and 74 to 76 are provided at one side for receiving the reference signal FR (the first input terminal 63) and at the other side for receiving the feedback signal FV (the second input terminal 73) respectively.

Suppose that the selection circuit 64 is supplied with the control signals k1 at the H level, k2 at the L level and k3 at the L level, and that the selection circuit 77 is supplied with the control signals k1 at the H level, k2 at the L level and k3 at the L level in the phase comparator 68.

At this time, the output of the NAND gate 65 is at the L level, the output of the NAND gate 66 is at the H level, the output of the NAND gate 67 is at the H level, and the output of the NAND gate 68 is at the H level. That is, by supplying the selection circuit 64 with the control signals k1, k2, k3 at the above specific levels, the delay circuit 60 can be selected as desired. As a result, the reference signal FR2 delayed by a first delay time in the delay circuit 60 is input into the clock terminal C of the flip-flop 69.

Likewise, by supplying the selection circuit 77 with the control signals k1, k2, k3 at the above specific levels, the delay circuit 74 can be selected as desired. As a result, the feedback signal FV2 delayed by the first delay time in the delay circuit 74 is input into the clock terminal C of the flip-flop 70.

Suppose that the selection circuit 64 is supplied with the control signals k1 at the L level, k2 at the H level and k3 at the L level, and that the selection circuit 77 is supplied with the control signals k1 at the L level, k2 at the H level and k3 at the L level in the phase comparator 69.

At this time, the output of the NAND gate 65 is at the H level, the output of the NAND gate 66 is at the L level, the output of the NAND gate 67 is at the H level, and the output of the NAND gate 68 is at the H level. That is, by supplying the selection circuit 64 with the control signals k1, k2, k3 at the above specific levels, the delay circuit 61 can be selected as desired. As a result, the reference signal FR3 delayed by a second delay time in the delay circuit 61 is input into the clock terminal C of the flip-flop 69.

Likewise, by supplying the selection circuit 77 with the control signals k1, k2, k3 at the above specific levels, the delay circuit 75 can be selected as desired. As a result, the feedback signal FV3 delayed by the second delay time in the delay circuit 75 is input into the clock terminal C of the flip-flop 70.

Suppose that the selection circuit 64 is supplied with the control signals k1 at the L level, k2 at the L level and k3 at the H level, and that the selection circuit 77 is supplied with the control signals k1 at the L level, k2 at the L level and k3 at the H level in the phase comparator 70.

At this time, the output of the NAND gate 65 is at the H level, the output of the NAND gate 66 is at the H level, the output of the NAND gate 67 is at the L level, and the output of the NAND gate 68 is at the H level. That is, by supplying the selection circuit 64 with the control signals k1, k2, k3 at the above specific levels, the delay circuit 62 can be selected as desired. As a result, the reference signal FR4 delayed by a third delay time in the delay circuit 62 is input into the clock terminal C of the flip-flop 69.

Likewise, by supplying the selection circuit 77 with the control signals k1, k2, k3 at the above specific levels, the delay circuit 76 can be selected as desired. As a result, the feedback signal FV4 delayed by the third delay time in the delay circuit 76 is input into the clock terminal C of the flip-flop 70.

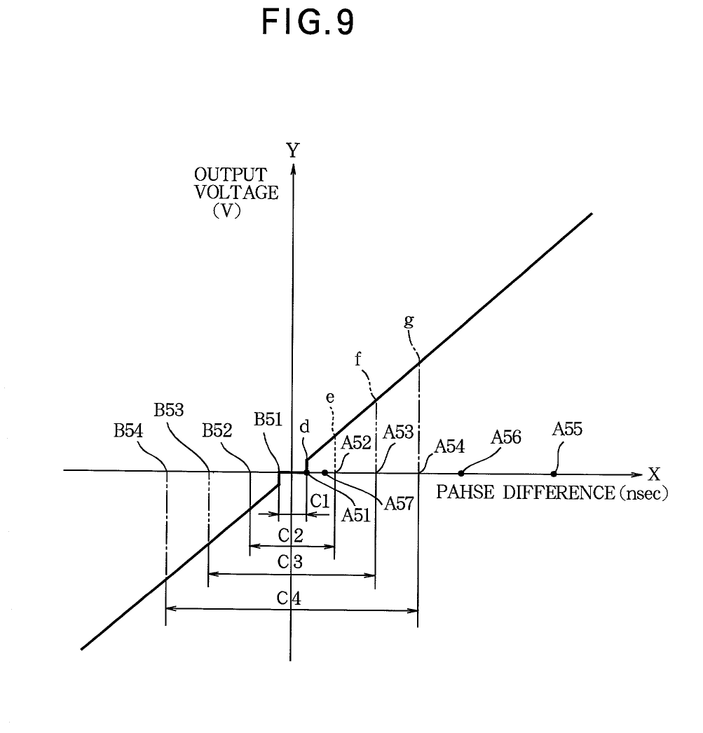

The phase comparators 67 to 70 will be further explained in detail with reference to FIG. 7 to FIG. 9. FIG. 9 is a view showing characteristics of the phase comparators 67 to 70. In FIG. 9, the horizontal axis represents the phase difference between the reference signal FR and the feedback signal FV, and the vertical axis represents the output voltages (pump-up signal, pump-down signal) of the phase comparators 67 to 70.

A characteristic of the phase comparator 67 is shown by d. In this characteristic, the output voltage becomes zero when the point A51 representing the smallest phase difference is reached. The phase comparator 67 may be the same as the phase comparators 68 to 70 (see FIG. 8) except that it has not the delay circuit 60, 61, 62, 74, 75, 76 and the selection circuits 64, 77.

Since the phase comparator 67 has not the delay circuits, the phase comparison between the reference signal FR1 and the feedback signal FV1 is performed with no delay. As a result, the output voltage becomes zero at the point A51 representing the smallest phase difference, and therefore the dead zone C1 is the smallest.

A characteristic of the phase comparator 68 is shown by e. In this characteristic, the output voltage becomes zero when the point A52 representing the second smallest phase difference is reached. In FIG. 8, when a pulse of the reference signal FR2 enters the first input terminal 63, it is delayed by the first delay time in the delay circuit 60. When a pulse of the feedback signal FV2 enters the second input terminal 73 subsequently, phase comparison between this pulse and the above delayed pulse is performed. As a result, the pump-up signal PU or pump-down signal PD is output from the first output terminal 71 or the second output terminal 82. By delaying the phase comparison timing by use of the delay circuits 60 and 74 as above, the output voltage of the phase comparator 68 becomes zero at the point A52 representing the second smallest phase difference. As a result, the dead zone C2 of the phase comparator 68 is the second smallest (see FIG. 9).

A characteristic of the phase comparator 69 is shown by f. In this characteristic, the output voltage becomes zero when the point A53 representing the third smallest phase difference is reached. In FIG. 8, when a pulse of the reference signal FR3 enters the first input terminal 63, it is delayed by the second delay time in the delay circuit 61. The delay circuit 61 is constituted by six inverters, while the delay circuit 60 is constituted by four inverters. Accordingly, the second delay time of the delay circuit 61 is longer than the first delay time of the delay circuit 60.

When a pulse of the feedback signal FV3 enters the second input terminal 73 subsequently, phase comparison between this pulse and the above delayed pulse is performed. As a result, the pump-up signal PU or pump-down signal PD is output from the first output terminal 71 or the second output terminal 82. By delaying the phase comparison timing by use of the delay circuits 61 and 75 as above, the output voltage of the phase comparator 69 becomes zero at the point A53 representing the third smallest phase difference. As a result, the dead zone C3 of the phase comparator 69 is the third smallest (see FIG. 9).

A characteristic of the phase comparator 70 is shown by g. In this characteristic, the output voltage becomes zero when the point A54 representing the fourth smallest phase difference is reached. In FIG. 8, when a pulse of the reference signal FR4 enters the first input terminal 63, it is delayed by the third delay time in the delay circuit 62. The delay circuit 62 is constituted by eight inverters, while the delay circuit 61 is constituted by six inverters. Accordingly, the third delay time of the delay circuit 62 is longer than the second delay time of the delay circuit 61.

When a pulse of the feedback signal FV4 enters the second input terminal 73, phase comparison between this pulse and the above delayed pulse is performed. As a result, the pump-up signal PU or pump-down signal PD is output from the first output terminal 71 or the second output terminal 82. By delaying the phase comparison timing by use of the delay circuits 62 and 76 as above, the output voltage of the phase comparator 70 becomes zero at the point A54 representing the fourth smallest phase difference. As a result, the dead zone C4 of the phase comparator 70 is the fourth smallest (see FIG. 9).

The above material is summarized as follows. The phase comparators 68 to 70 are each provided with a plurality of the delay circuits 6o to 62 and 74 to 76 at their inputs. By selecting from among the delay circuits 60 to 62, 74 to 76 by use of the control signals k1 to k3, a desired dead zone is selected.

For example, by selecting the delay circuits 60 and 74, the dead zone C2 can be obtained. It matches the characteristic e of the phase comparator 68. By selecting the delay circuits 61 and 75, the dead zone C3 can be obtained. It matches the characteristic f of the phase comparator 69. By selecting the delay circuits 62 and 76, the dead zone C4 can be obtained. It matches the characteristic g of the phase comparator 70.

As explained above, at least one of the phase comparators is configured to have an adjustable dead zone (the phase comparators 68 to 70 in this explanation). That is, the dead zones C2, C3, C4 of the phase comparators 68 to 70 are adjustable.

Furthermore, it is possible to select, for example, the delay circuits 60 and 75 in the phase comparator 68 so that the points at which the output voltage becomes zero are the points B53 and A52. The dead zone of the phase comparator 68 ranges from the point 53B to the point A52 in this case.

The operation of the PLL device according to this embodiment will be explained with reference to FIG. 7 to FIG. 9. In these FIGS., when the user presses the start button, a start signal is input into the control unit 26.

The control unit 26 allows supply of the source voltage to the components shown in FIG. 7 in response to the start signal. The reference oscillator 2 outputs the reference signals FR1 to FR4. The control signals G1 to G4 are still at the L level at this time. The gates 22 to 25 are closed, and the variable frequency dividers 11 to 14 do not perform frequency division operations.

The control unit 26 switches the control signal G1 to the H level, and outputs an H-level signal to the gate 22 after a lapse of a predetermined time after reception of the start signal. As a result, the variable frequency divider 11 begins frequency division operation to supply the phase comparator 67 with the feedback signal FV1 resulting from dividing the feedback signal FV1 by a set frequency-division ratio.

When the reference signal FR1 rises after a lapse of time, the phase comparator 67 compares phases between the reference signal FR1 and the feedback signal FV1, and outputs the error signal ER1 to the low-pass filter 21 through the charge pump 17.

After a further lapse of time, the control unit 26 switches the control signal G2 to the H level, and opens the gate 23.

The gate 22 is left open at this time. The variable frequency divider 12 begins frequency division operation at this time, and outputs the feedback signal FV2 to the phase comparator 68. When the reference signal FR2 rises after a lapse of time, the phase comparator 68 compares phases between the reference signal FR2 and the feedback signal FV2, and outputs the error signal ER2 to the low-pass filter 21 through the charge pump 18.

After a further lapse of time, the control unit 26 switches the control signal G3 to the H level, and opens the gate 24.

The gate 23 is left open at this time. The variable frequency divider 13 begins frequency division operation at this time, and outputs the feedback signal FV3 to the phase comparator 69. When the reference signal FR3 rises after a lapse of time, the phase comparator 69 compares phases between the reference signal FR3 and the feedback signal FV3, and outputs the error signal ER3 to the low-pass filter 21 through the charge pump 19.

After a further lapse of time, the control unit 26 switches the control signal G4 to the H level, and opens the gate 25. The gate 24 is left open at this time.

The variable frequency divider 14 begins frequency division operation at this time, and outputs the feedback signal FV4 to the phase comparator 70. When the reference signal FR4 rises after a lapse of time, the phase comparator 70 compares phases between the reference signal FR4 and the feedback signal FV4, and outputs the error signal ER4 to the low-pass filter 21 through the charge pump 20.

To summarize the material above, the control unit 26 causes the variable frequency dividers 11 to 14 to start frequency division operations in synchronization with the phases of the reference signals FR1 to FR4. The phase comparators 67, 68, 69, 70 each compare phases between the reference signals FR1 to FR4 and the feedback signals FV1 to FV4. As results, the phase comparators 67 to 70 output the error signals ER1 to ER4 to the low-pass filter 21 through the charge pumps 17 to 20 respectively.

The low-pass filter 21 outputs the control voltage CV to the voltage-controlled oscillator 15 in response to the error signals ER1 to ER4. The voltage-controlled oscillator 15 generates the output signal FO in response to the control voltage CV. Such a state is represented by a point A55 (see FIG. 9 ). The phase difference between the reference signal FR and the feedback signal FV is large in this state.

As described above, the reference oscillator 2 generates the reference signal FR1 having the reference frequency FR (period TR=1/FR). The reference signals FR2, FR3, FR4 are produced by delaying the reference signal FR1 in steps of ¼ period (TR/4) sequentially.

The reference signals FR1 to FR4 have different phases (they are out of phase with each other by π/2 in this explanation), and phase comparisons are performed for each of the reference signals FR1 to FR4. As a result,phase comparisons are performed multiple times during one period (TR) of the reference signal FR1, and accordingly the lock-up time is shortened to approximately ¼ of the conventional time.

As time elapses and the above phase comparisons are repeated, the phase of the feedback signal FV resulting from dividing the frequency of the output signal FO approaches the reference signal FR (see the point A56 in FIG. 9). If this state is referred to as “unlocked state”, the four stages (the phase comparators 67, 68, 69, 70) operate simultaneously to output the error signals ER1 to ER4 to the low-pass filter 21 through the charge pumps 17 to 20 in this unlocked state.

After a further lapse of time, through repetition of phase comparisons, the phase difference between the reference signal FR and the feedback signal FV reaches the point A54. At this time, as shown in FIG. 9, the output of the phase comparator 70 having the characteristic g becomes zero, so the error signal ER4 output from the charge pump 20 connected to the phase comparator 70 becomes zero.

If the point A54 is referred to as “nearly-locked state”, only the phase comparators 67 to 69 deliver outputs in this state. As described above, the number of the output stages is four (phase comparators 67 to 70) at the points A55 and A56, while it becomes three when the point A54 is reached.

After a further lapse of time, through repetition of phase comparisons, the phase difference between the reference signal FR and the feedback signal FV reaches the point A53. At this time, as shown in FIG. 9, the output of the phase comparator 69 having the characteristic f becomes zero, so the error signal ER3 output from the charge pump 19 connected to the phase comparator 69 becomes zero. Only the phase comparators 67 and 68 deliver outputs at this time. As described above, the number of the output stages becomes two (phase comparators 67 and 68) when the point A53 is reached.

Through repetition of phase comparisons, the phase difference reaches the point A52. At this time, as shown in FIG. 9, the output of the phase comparator 68 having the characteristic e becomes zero, so the error signal ER2 output from the charge pump 18 connected to the phase comparator 68 becomes zero. Only the phase comparator 67 delivers outputs at this time. As described above, the number of the output stages becomes one (phase comparator 67) when the point A52 is reached.

Through further repetition of phase comparisons, the phase difference between the reference signal FR and the feedback signal FV reaches the point A51. At this time, as shown in FIG. 9, the output of the phase comparator 67 having the characteristic d becomes zero, so the error signal ER1 output from the charge pump 17 connected to the phase comparator 67 becomes zero. As described above, the number of the output stages of the phase comparators 7 to 10 becomes zero when the point A51 is reached.

By setting the point A51 smaller than the point A57 at which the PLL device 1 enters the “locked state”, this PLL device can be maintained within the locked state by the output of the phase comparator 67.

To summarize the material above, the phase comparators 68 to 70 are configured to have adjustable dead zones. Accordingly, as shown in FIG. 9, the phase comparators 67 to 70 are caused to deliver outputs in four stages over the period from the point A55 to a point immediately before the point A54 to increase the number of phase comparisons during one period of the reference signal FR (four times the conventional number) and move up the start-up (reduction of the lock-up time).

Over the period from the point A54 to a point immediately before the point A53, the phase comparators 67 to 69 are caused to deliver outputs in three stages. Over the period from the point A53 to a point immediately before the point A52, the phase comparators 67 and 68 are caused to deliver outputs in two stages. Over the period from the point A52 to a point immediately before the point A51, only the phase comparator 67 is caused to deliver an output in one stage. As explained above, by reducing gradually the number of the output stages of the phase comparators 57 to 60 after the nearly-locked state (point A54) is reached, it is possible to avoid interference between the outputs of the phase comparators 67 to 70.

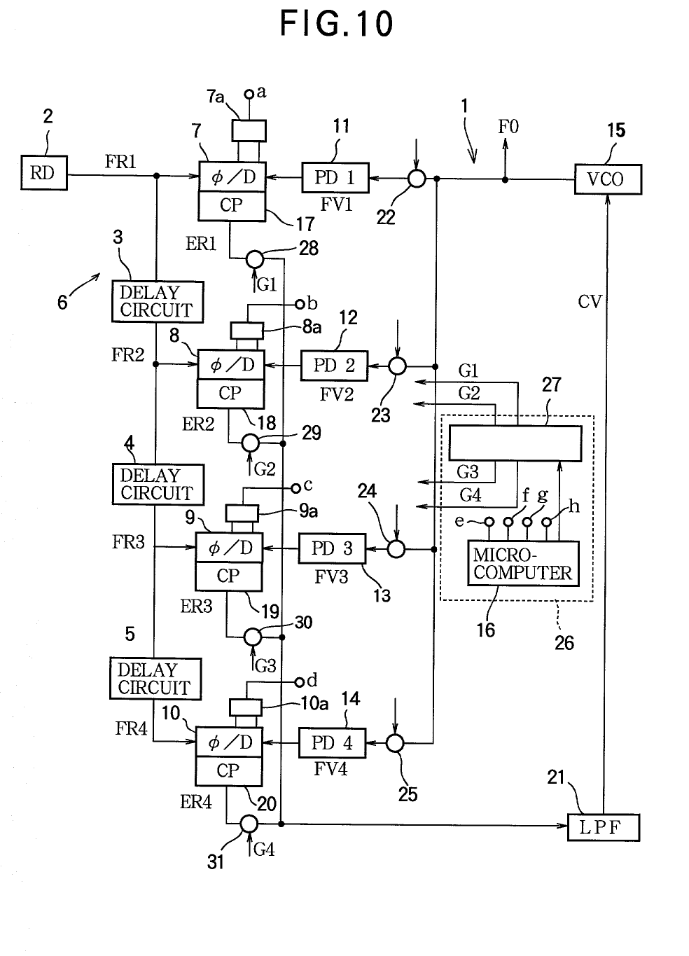

A PLL device 1 according to a fourth embodiment of the invention will be explained with reference to a block diagram of FIG. 10. In FIG. 10, the elements that are the same as those in FIG. 1 are given the same reference characters, and explanation thereof will be omitted.

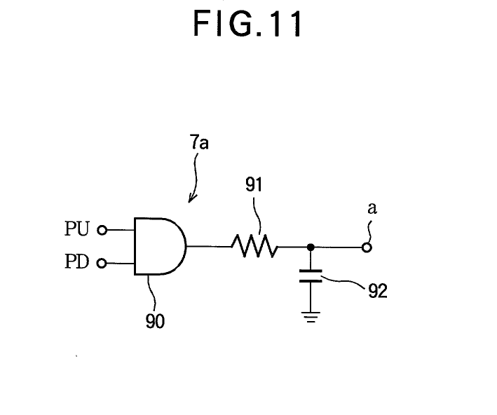

FIG. 11 shows a circuit structure of a detector 7a. The detector 7a is comprised of an AND gate 90, a resistor 91, a capacitor 92, etc. The pump-up signal and pump-down signal are input into the AND gate 90. In the locked state, both of the pump-up signal and pump-down signal are at the H level, and accordingly the output of the AND gate 90 is at the H level so the capacitor 92 is charged through the resistor 91 and a voltage at a terminal a therefore rises. The voltage at the terminal a is applied to a terminal e of a microcomputer 16. In this way, the locked state is detected by the detector 7a. Detectors 8a to 10a, which have the same structure as the detector 7a, each supply locked state detection signals to terminals f, g, h of the microcomputer 16 through terminals b, c, d.

The PLL device according to the fourth embodiment has gates 28 to 31 in addition to gates 22 to 25. The gate 28 is provided between the output of a charge pump 17 and the input of a low-pass filter 21. The gate 29 is provided between the output of a charge pump 18 and the input of the low-pass filter 21. The gate 30 is provided between the output of a charge pump 19 and the input of the low-pass filter 21. The gate 31 is provided between the output of a charge pump 20 and the input of the low-pass filter 21.

A control signal G1 is supplied to the gate 28, a control signal G2 is supplied to the gate 29, a control signal G3 is supplied to the gate 30, and a control signal G4 is supplied to the gate 31.

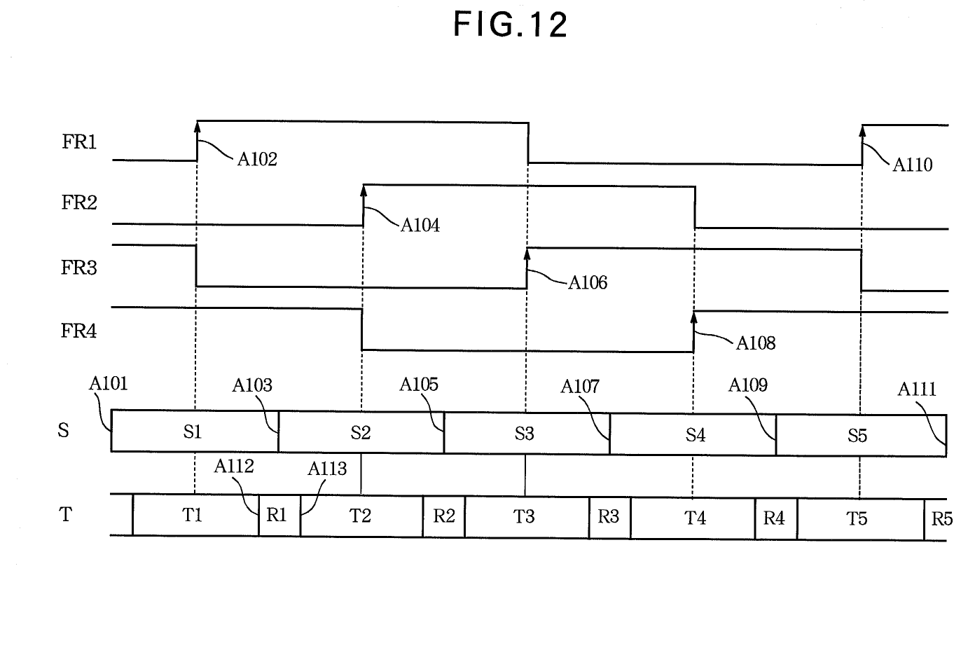

The operation of the PLL device according to this embodiment will be explained with reference to FIG. 10 and FIG. 12. FIG. 12 is a timing diagram of various signals in the PLL device. In these FIGS., when a user presses a start button, a start signal is input into a control unit 26.

The control unit 26 allows supply of the source voltage to the components shown in FIG. 10 in response to the start signal. A reference oscillator 2 outputs reference signals FR1 to FR4. The control signals G1 to G4 are still at the L level at this time. Accordingly the gates 28 to 31 are closed, and the outputs of phase comparators 7 to 10 are disabled. The gates 22 to 25 are closed as well, and variable frequency dividers 11 to 14 do not perform frequency division operations.

The control unit 26 switches the control signal G1 to the H level, and outputs an H-level signal to the gate 22 after a lapse of a predetermined time after reception of the start signal. In FIG. 12, outputting periods of the phase comparators 7 to 10 are shown by S. As a consequence, the variable frequency divider 11 begins frequency division operation, and outputs a feedback signal FV1 resulting from dividing an output signal FO by a set frequency-division ratio to the phase comparator 7. The phase comparator 7 is in the enabled state since the gate 28 is open at this time.

When the reference signal FR1 rises after a lapse of time (A102 in FIG. 12), the phase comparator 7 compares phases between the reference signal FR1 and the feedback signal FV1, and outputs an error signal ER1 to the low-pass filter 21 through the charge pump 17 slightly behind A102.

After a further lapse of time (A103 in FIG. 12), the control unit 26 switches the control signal G1 to the L level, switches the control signal G2 to the H level, and opens the gate 23. The gate 22 is left open at this time. As a consequence, the gate 28 is closed, and the outputting period (enabled-state period) S1 of the phase comparator 7 terminates. As shown in FIG. 12, the outputting period S1 is set such that the rising edge of the reference signal FR1 (A102) is situated at approximately its center.

The variable frequency divider 12 begins frequency b division operation to output a feedback signal FV2 to a phase comparator 8 at this time. The phase comparator 8 is in the enabled state since the gate 29 is open.

When the reference signal FR2 rises after a lapse of time (A104 in FIG. 12), the phase comparator 8 compares phases between the reference signal FR2 and the feedback signal FV2, and outputs an error signal ER2 to the low-pass filter 21 through the charge pump 18 slightly behind A104.

After a further lapse of time (A105 in FIG. 12), the control unit 26 switches the control signal G2 to the L level, switches the control signal G3 to the H level, and opens the gate 24. The gate 23 is left open at this time. As a consequence, the gate 29 is closed, and the outputting period (enabled-state period) S2 of the phase comparator 8 terminates. As shown in FIG. 12, the outputting period S2 is set such that the rising edge of the reference signal FR2 (A104) is situated at approximately its center.

The variable frequency divider 13 begins frequency division operation to output a feedback signal FV3 to a phase comparator 9 at this time. The phase comparator 9 is in the enabled state since the gate 30 is open. When the reference signal FR3 rises after a lapse of time (A106 in FIG. 12), the phase comparator 9 compares phases between the reference signal FR3 and the feedback signal FV3, and outputs an error signal ER3 to the low-pass filter 21 through the charge pump 19 slightly behind A106.

After a further lapse of time (A107 in FIG. 12), the control unit 26 switches the control signal G3 to the L level, switches the control signal G4 to the H level, and opens the gate 25. The gate 24 is left open at this time. As a consequence, the gate 30 is closed, and the outputting period (enabled-state period) S3 of the phase comparator 9 terminates. As shown in FIG. 12, the outputting period S3 is set such that the rising edge of the reference signal FR3 (A106) is situated at approximately its center.

The variable frequency divider 14 begins frequency division operation to output a feedback signal FV4 to a phase comparator 10 at this time. The phase comparator 10 is in the enabled state since the gate 31 is open. When the reference signal FR4 rises after a lapse of time (A108 in FIG. 12), the phase comparator 10 compares phases between the reference signal FR4 and the feedback signal FV4, and outputs an error signal ER4 to the low-pass filter 21 through the charge pump 20 slightly behind A108.

After a further lapse of time (A109 in FIG. 12), the control unit 26 switches the control signal G4 to the L level, switches the control signal G1 to the H level. The gate 25 is left open at this time. As a consequence, the gate 31 is closed, and the outputting period (enabled-state period) S4 of the phase comparator 10 terminates. As shown in FIG. 12, the outputting period S4 is set such that the rising edge of the reference signal FR4 (A108) is situated at approximately its center.

The variable frequency divider 11 is performing frequency division operation to output the feedback signal FV1 to the phase comparator 7 at this time. The phase comparator 7 is in the enabled state since the gate 28 is open. When the reference signal FR1 rises after a lapse of time (A110 in FIG. 12), the phase comparator 7 compares phases between the reference signal FR1 and the feedback signal FV1, and outputs the error signal ER1 to the low-pass filter 21 through the charge pump 17 slightly behind A110.

After a further lapse of time (A111 in FIG. 12), the control unit 26 switches the control signal G1 to the L level, switches the control signal G2 to the H level. As a consequence, the gate 28 is closed, and the outputting period (enabled-state period) S5 of the phase comparator 7 terminates. As shown in FIG. 12, the outputting period S5 is set such that the rising edge of the reference signal FR1 (A110) is situated at approximately its center. Through repetition of the above-explained operation in the PLL device, the output signal FO has the set frequency eventually.

To summarize the material above, the phase comparators 7, 8, 9, 10 compare phases between the reference signals FR1, FR2, FR3, FR4 and the feedback signals FV1, FV2, FV3, FV4 to output the error signals ER1, ER2, ER3, ER4 to the low-pass filter 21. Accordingly, the outputting periods (enabled-state periods) S1, S2, S3, S4, S5 . . . are set so as to be in synchronization with the phases (A102, A104, A106, A108, A110) of the reference signals FR1 to FR4.

To be more specific, the outputting periods S1, S2, S3, S4, S5 . . . are set such that the rising edges of the reference signals FR1 to FR4 (A102, A104, A106, A108 . . . ) are situated at approximately their centers. It is permissible to set the outputting periods such that the falling edges of the reference signals are situated at approximately their centers.

As described above, by switching the control signals G1 to G4 at A101, A103, A105, A107, A109, A111 . . . (for example, by switching the control signal G1 from the H level to the L level and switching the control signal G2 from the L level to the H level at A103), the outputting periods S1, S2, S3, S4, S5 . . . can be set so as not to overlap each other.

Another control operation different from the control operation described above will be explained with reference to FIG. 10 and FIG. 12. In FIG. 12, outputting periods of the phase comparators 7 to 10 are shown by T. Outputting periods T1 to T5 are slightly shorter than the outputting periods S1 to S5 described above, and suspension periods R1, R2, R3, R4, R5 . . . during which the phase comparators 7 to 10 are disabled are interposed between neighboring outputting periods.

The control unit 26 switches the control signal G1 from the H level to the L level at A112 which is slightly ahead of A103 to close the gate 28 and put the phase comparator 7 in the disabled state. The control unit 26 switches the control signal G2 from the L level to the H level at A113 which is slightly behind A103 to open the gate 29 and put the phase comparator 8 in the enabled state. As a result, all the gates 28 to 31 are closed during the suspension period R1 (the period from A112 to A113) to put the phase comparators 7 to 10 in the disabled state.

As described above, the detectors 7a to 10a deliver ANDs of the pump-up signals and the pump-down signals output from the phase comparators 7 to 10 to the control unit 26 as detection signals. The control unit 26 decides that the locked state (steady state) is reached when any one of the detection signals from the detectors reaches a first threshold.

The control unit 26 sets a second threshold to 90% of the first threshold, and decides that the nearly-locked state is reached when any one of the detection signals reaches this second threshold.

The control unit 26 may start the operation as shown in FIG. 12 (in which the outputting periods S1 to S5 are set in synchronization with the phases of the reference signals FR1 to FR4 so as not to overlap each other) upon deciding that the nearly-locked state is reached. The control unit 26,may let the phase comparators 7 to 10 deliver outputs throughout the period (start-up period) until it decides that the nearly-locked state is reached. That is, the outputting periods of the phase comparators 7 to 10 may overlap each other.

In the above explanation, a plurality of the phase comparators 7 to 10 are provided with a plurality of the variable frequency dividers 11 to 14 which output the feedback signals FV1 to FV4. However, the present invention is not confined therein, and it is permissible to provide only one variable frequency divider.

That is, it is permissible to connect an input of one variable frequency divider to the voltage-controlled oscillator 15 and connect an output of this variable frequency divider to the phase comparators 7 to 10.

Furthermore, the numbers of the variable frequency dividers and the phase comparators are four in the first to fourth embodiments described above, however, the present invention is not confined therein. For example, it is possible to replace the four variable frequency dividers with one variable frequency divider that serves the functions of these four frequency dividers through time sharing operation. Likewise, it is possible to replace the four phase comparators with one phase comparator that serves the functions of these four phase comparators through time sharing operation.

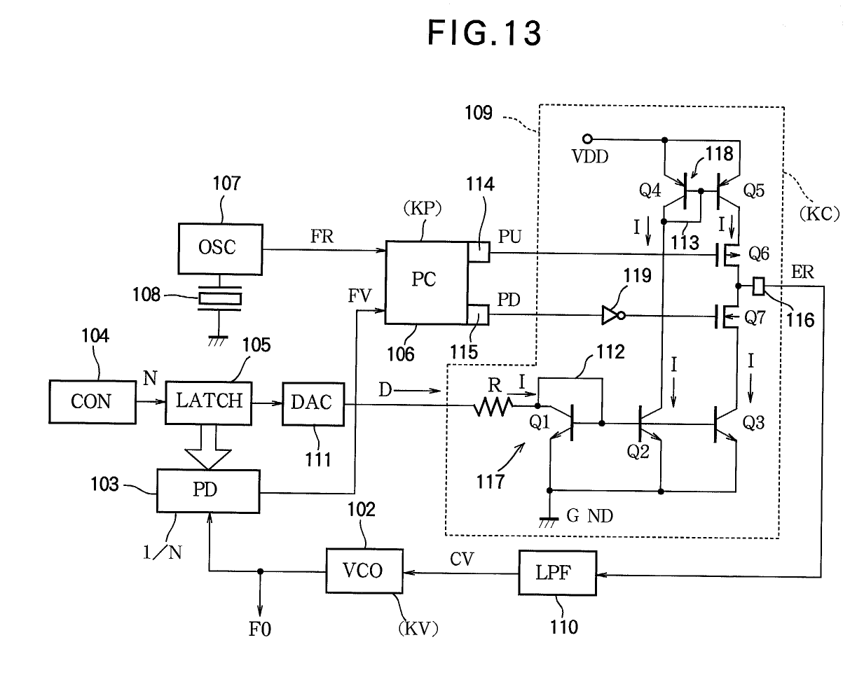

A PLL device according to a fifth embodiment of the invention will be explained with reference to a circuit diagram of FIG. 13. In FIG. 13, a voltage-controlled oscillator 102 outputs an output signal FO. The output signal FO is input into a variable frequency divider 103. A control unit 104, which is comprised of a microcomputer or the like, outputs a frequency-division ratio N (a value of a digital signal) to a latch circuit 105. The latch circuit 105 outputs the frequency-division ratio N (digital value) to the variable frequency divider 103. The variable frequency divider 103 divides the output signal FO from the voltage-controlled oscillator 102 by the frequency-division ratio N, and outputs a signal (a feedback signal FV) resulting from this frequency division to a phase comparator 106.

A reference oscillator 107 has an input connected to a quartz oscillator 108 and an output connected to the phase comparator 106. The reference oscillator 107 generates a reference signal FR, for example, of 10 kHz, and outputs it to the phase comparator 106.

The phase comparator 106 compares phases between the feedback signal FV and the reference signal FR, and outputs a first output signal (pump-down signal) PD and a second output signal (pump-up signal) PU to a charge pump 109 as a result of the comparison. The charge pump 109 outputs an err signal ER to a low-pass filter 110 in response to the outputs PD and PU of the phase comparator 106.

The low-pass filter 110, which is comprised of resistors, capacitors, an operational amplifier, etc. (not shown), amplifies the error signal ER and supplies it to the voltage-controlled oscillator 102 as a control signal CV whose high-frequency component has been cut. The voltage-controlled oscillator 102 outputs the output signal FO having a frequency responsive to the control voltage CV to the variable frequency divider 103.

AD/A converter 111 converts the frequency-division ratio N (digital value) received from the latch circuit 105 into an analog value to supply the charge pump 109 with an output voltage D which is proportional to the frequency-division ratio N.

The charge pump 109 is comprised of, for example, a resistor R transistors Q1, Q2, Q3, Q4, Q5, Q6, Q7, etc. The transistor Q1 has a collector connected to the output of the D/A converter 111 through the resistor R, an emitter connected to the ground, and a base connected to a base of the transistor Q2. The collector and the base of the transistor Q1 are interconnected through a lead 112.

The transistor Q2 has an emitter connected to the ground and a collector connected to a base of the transistor Q4. The transistor Q3 has a base connected to the base of the transistor Q2, an emitter connected to the ground and a collector connected to a source of the transistor Q7 (comprised of, for example, an n-channel MOS FET; referred to as a first switching unit here in after).

An emitter of the transistor Q4 is connected to a source voltage supply terminal VDD, and the base of the transistor Q4 is connected to a base of the transistor Q5. The base and collector of the transistor Q4 are interconnected through a lead 113.

The transistor Q6 (comprised of, for example, a p-channel MOS FET; referred to as a second switching unit here in after) has a drain connected to the base of the transistor Q5. A gate of the second switching unit Q6 is connected to a second output terminal 114 of the phase comparator 106. A source of the second switching unit Q6 is connected to a drain of the first switching unit Q7.

A node of the source and the drain is connected to one end of an output terminal 116, and the low-pass filter 110 is connected to the other end of the output terminal 116. A gate of the first switching unit Q7 is connected to a first output terminal 115 of the phase comparator 106 through an inverter 119.

The resistor R, the lead 112, the transistors Q1, Q2, Q3, etc. constitute a first mirror circuit 117, so the currents flowing through the collectors of the transistors Q1, Q2, Q3 respectively have the same current value I. This current value I is determined by the output voltage D, the resistor R, and the transistor Q1. That is, the current value I is responsive to the output voltage D, and increases as the frequency-division ratio N increases. The first switching unit Q7 is connected to the first mirror circuit 117.

Similarly, the lead 113, the transistors Q4, Q5, etc. constitute a second mirror circuit 118, so the currents flowing through the collectors of the transistors Q4, Q5 respectively have the same current value I which is the same as the current flowing through the first mirror circuit 117. The second switching unit Q6 is connected to the second mirror circuit 118. The PLL device of this embodiment is constituted by the above-described components.

The operation of this PLL device will be explained with reference to FIG. 13. A user sets a desired frequency A (kHz) to a frequency setting unit (not shown) connected to the control unit 104.

The control unit 104 computes the frequency-division ratio N (analog value) by dividing the frequency A by 10 since the frequency of the reference signal FR is 10 kHz. The control unit 104 converts the analog value into data (digital value comprised of a plurality of bits) representing the frequency-division ratio N by use of a built-in A/D converter. The control unit 104 outputs the data of the frequency-division ratio N to the latch circuit 105. The D/A converter 111 converts the data into an analog value and supplies the output voltage D which is proportional to the frequency-division ratio N to the charge pump 109. The latch circuit 105 outputs the frequency-division ratio N (digital value) to the variable frequency divider 103.

The variable frequency divider 103 divides the output signal FO received from the voltage-controlled oscillator 102 by the frequency-division ratio N, and outputs a signal (feedback signal FV) resulting from this frequency division to the phase comparator 106. The phase comparator 106 compares phases between the reference signal FR output from the reference oscillator 107 and the feedback signal FV.

The above explanation is for the PLL device in the start-up state (when the frequency of the output signal FO has not reached the set frequency yet). Accordingly, the phase comparator 106 brings the first output signal PD (pump-down signal) output from the first output terminal 115 to the H level as a result of the phase comparison. The phase comparator 106 also brings the second output signal PU (pump-up signal) output from the second output terminal 114 to the L level as a result of the phase comparison.

Since the first output signal PD (H level) output from the first output terminal 115 is inverted by the inverter 119, and the gate of the first switching unit Q7 is therefore supplied with an L-level signal, the first switching unit Q7 turns off. Since the gate of the second switching unit Q6 connected to the second output terminal 114 is supplied with the second output signal PU (L level), the second switching unit Q6 turns on.

As a result, the currents I flow through the collectors of the transistors Q1, Q2 that constitute the first mirror circuit 117, and the same currents I flow through the collectors of the transistors Q4, Q5 that constitute the second mirror circuit 118.

Since the first switching unit Q7 is off and the second switching unit Q6 is on at this time, the current I flows into the low-pass filter 110 through the transistor Q5, the second switching unit Q6, and the output terminal 116.

The above material is summarized as follows. When the -phase comparator 106 supplies the second output signal PU at the L level to the second switching unit Q6, the second switching unit Q6 turns on. The current I that is the same as the current flowing through the first mirror circuit 117 is discharged (supplied) to the low-pass filter 110 as the output current (error signal ER) of the charge pump 109. As described above, since the current I has a value related to the output voltage D which is proportional to the frequency-division ratio N, it increases as the frequency-division ratio N increases.

Through repetition of such phase comparisons, the PLL device reaches the locked state (the frequency of the output signal FO reaches the set frequency). If the frequency of the output signal FO exceeds the set frequency, the phase comparator 106 brings the first output signal PD output from the first output terminal 115 to the L level. The phase comparator 106 also brings the second output signal PU output from the second output terminal 114 to the H level.

Since the first output signal PD (L level) output from the first output terminal 115 is inverted by the inverter 119, and the gate of the first switching unit Q7 is therefore supplied with an H-level signal, the first switching unit Q7 turns on. Furthermore, since the gate of the second switching unit Q6 connected to the second output terminal 114 is supplied with the second output signal PU (H level) the second switching unit Q6 turns off.

As a consequence, the currents I flow through the collectors of the transistors Q1, Q2, Q3 that constitute the first mirror circuit 117, and the same current I flows through the collector of the transistor Q4 that constitutes the second mirror circuit 118.

Since the first switching unit Q7 is on and the second switching unit Q6 is off at this time, the current I flows from the low-pass filter 110 to the ground through the output terminal 116, the first switching unit Q7, and the transistor Q3.

The above material is summarized as follows. When the phase comparator 106 outputs the first output signal PD at the L level,the first switching unit Q7 turns on. Then,the current I drawn from the low-pass filter 110 as the output current of the charge pump 109 (error signal ER) flows through the first mirror circuit 117. Since the current I has a value related to the output voltage D which is proportional to the frequency-division ratio N, it increases as the frequency-division ratio N increases.

As described above, the output current (error signal ER) of the charge pump 109 varies with the output related to the frequency-division ratio N (for example, the output voltage D which is proportional to the frequency-division ratio N) when the phase comparator 106 outputs either the first output signal PD (L level) or the second output signal PU (L level). That is, the output current (current value I) increases as the frequency-division ratio N increases.

In the configuration where the current I is set to be in proportion to the frequency-division ratio N, the following equation holds. I=C1·N (C1 being a constant). If an output current I1 is fixed and independent of the frequency-division ratio N as is the case with a conventional charge pump, the following equation holds. I1=C2 (C2 being a constant). In this case, a gain KC of the charge pump 109 is obtained from the following equation.

KC=C1·N/C2 Eq. (1)

An overall gain K of the PLL device is obtained from the following equation.

K=KP*KC·KV/N Eq. (2)

where KP and KV are a gain of the phase comparator 106 and a gain of the voltage-controlled oscillator 102 respectively. Substituting Eq. (1) into Eq. (2) gives the following equation.

K=KP·(C1·N/C2)·KV/N=KP·C1·KV/C2

By configuring the charge pump 109 to have such a gain KC as remains proportional to the frequency-division ratio N, the overall gain K of the PLL device 1 is of a constant value that is independent of the frequency-division ratio N.

The current value I can be altered in accordance with the output related to the frequency-division ratio N (output voltage D, for example). As explained above, the gain KC of the charge pump 109 can be altered in accordance with the output related to the frequency-division ratio N.

As a result, when the gain KC of the charge pump 109 related to the frequency-division ratio N is multiplied by 1/N which is the gain of the variable frequency divider 103, effects of the frequency-division ratio N are canceled out, and therefore, the overall gain K of the PLL device 1 is of the constant value that is independent of the frequency-division ratio N.

Accordingly, the overall gain of the PLL device does not reduce as previously after the frequency-division ratio N of the variable frequency divider is changed to have a larger value, and the lock-up time is therefore shortened. Furthermore, since the overall gain is approximately constant even when the frequency-division ratio N is changed, the natural angular frequency and the damping factor are maintained at their optimum values. Accordingly, it is possible to prevent the stability and converging speed of the PLL device from lowering.

### Industrial Applicability

The PLL device according to the first embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with the phases of a plurality of the reference signals, a frequency of an output (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (7, 17, 8, 18, 9, 19, 10, 20) for comparing phases between the reference signals and the feedback signals corresponding to the reference signals to produce a plurality of error signal (ER1, ER2, ER3, ER4) a control voltage generating means (21) for producing the control voltage (CV) to be supplied to the voltage-controlled oscillator from the error signals output from the phase comparison means; and

a control means (16, 26, 27) that stops production of a specific one of a plurality of the error signals in accordance with a phase difference between at least one of a plurality of the feedback signals and a reference signal corresponding to the one of a plurality of the feedback signals.

With the above configuration, it is possible to perform phase comparisons multiple times during one period of the reference signal before lock-up, so the lock-up time is shortened. It is also possible to prevent the outputs of the phase comparators that are out of use (or the error signals that are out of use) interfere with the outputs of the phase comparators that are in use (or the error signals that are in use).

The phase comparison means may be comprised of a plurality of phase comparators having charge pumps (17, 18, 19, 20) whose outputs are connected to the control voltage generating means (21), the control means bringing a phase comparator that should stop production of the error signal to the high-impedance state.

By bringing phase comparators to be out of use to the high-impedance state, it is possible to prevent the outputs of the phase comparators that are out of use (or the error signals that are out of use) interfere with the outputs of the phase comparators that are in use (or the error signals that are in use). As a result, it is possible to avoid lock failure (sudden change from the locked state to the non-locked state) in the configuration where the number of the phase comparators in use is reduced.

The phase comparators (7, 8, 9, 10) may have detectors (7a, 8a, 9a, 10a) for detecting a state in which the phase difference between the reference signal and the feedback signal is smaller than a predetermined value, the control means bringing at least specific one of the phase comparators to the high-impedance state when a detector of at least one of the phase comparators has detected the above state.

By bringing the charge pump of the specific phase comparator to the high-impedance state when the detector has detected the locked state or the nearly-locked state as above, an excess of the output signal over a target frequency (overshoot) is reduced and the lock-up time is shortened correspondingly.

The control means may break connection between the phase comparator that should stop outputting the error signal and the control voltage generating means and, after a lapse of a predetermined time, break connection between the variable frequency divider connected to the phase comparator whose connection with the control voltage generating means has been broken and the voltage-controlled oscillator.

Thus, in the configuration where the number of the phase comparators in use is reduced, all the variable frequency dividers are caused to continue performing frequency division operations for a certain period of time after the phase comparators to be out of use are disabled. As a result, it is possible to prevent undesired outputs of the phase comparators that are out of use from being delivered to the control voltage generating means such as a low-pass filter when the number of the phase comparators in use is reduced, which enables smooth establishment of lock and avoids lock failure.

The PLL device according to the second embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with the phases of a plurality of the reference signals, a frequency of an output (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (57, 17, 58, 18, 59, 19, 60, 20) for comparing phases between the reference signals and the feedback signals corresponding to the reference signals to produce a plurality of error signals (ER1, ER2, ER3, ER4); and

a control voltage generating means (21) for producing the control voltage (CV) to be supplied to the voltage-controlled oscillator from the error signals output from the phase comparison means;

wherein the phase comparison means has a first dead zone (D1) to be used for producing at least one specific error signal (ER1) that is one of a plurality of the error signals, and a second dead zone (D2) to be used for producing the other error signals (ER2, ER3, ER4).

With this configuration, phase comparisons are performed multiple times during one period of the reference signal, so locking time (start-up) is shortened. Since the number of the phase comparator stages in use (or the number of the error signals in use) can be switched automatically when the phase of the output signal approaches the phase of the reference signal by the provision of the first and second dead zones, any controller for controlling the timing of the switching is unnecessary and the cost is therefore low. Furthermore, the previously occurring interference between the outputs (or the error signals) of the phase comparators due to shift of the timing of the switching can be avoided.

The phase comparison means may be comprised of a first phase comparator (57) having a smaller dead zone and a second phase comparator (58, 59, 60) having a larger dead zone, both the first phase comparator and the second phase comparator supplying the error signals to the control voltage generating means (21) while the phase difference between the output signal (FO) and the reference signal (FR) is large, only the first phase comparator supplying the error signal to the control voltage generating means after the phase difference becomes small.

Since the first phase comparator and the second phase comparator supply the error signals in the unlocked state (during start-up of the PLL device), phase comparisons are performed multiple times during one period of the reference signal and the locking time is therefore shortened. Furthermore, since only the first phase comparator delivers an output after the nearly-locked state is reached, it is possible to prevent the output of the second phase comparator from interfering with the output of the first phase comparator. Moreover, since the phase comparison means controls by itself the number of the phase comparators in use, any lock detector and controller previously used for controlling the number of the phase comparators in use are unnecessary.

The second phase comparator (58, 59, 60) may be provided with a first delay circuit (40) for delaying the incoming reference signal and a second delay circuit (47) for delaying the incoming feedback signal.

With this configuration, it is possible to obtain (define) the span of the dead zone of the second phase comparator.

The PLL device according to the third embodiment of the invention includes:

means (6) for generating a plurality of reference signals (FR1, FR2, FR3, FR4) having mutually differing phases;

a single variable frequency divider or a plurality of variable frequency dividers (11, 12, 13, 14) for dividing, in synchronization with the phases of a plurality of the reference signals, a frequency of an output (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (67, 17, 68, 18, 69, 19, 70, 20) for comparing phases between the reference signals and the feedback signals corresponding to the reference signals to produce a plurality of error signals (ER1, ER2, ER3, ER4); and

a control voltage generating means (21) for producing the control voltage (CV) to be supplied to the voltage-controlled oscillator from the error signals output from the phase comparison means;

wherein the phase comparison means has a first dead zone (C1) used for producing at least one specific error signal (ER1) that is one of a plurality of the error signals, and a second dead zone (C2, C3, C4) used for producing the other error signals (ER2, ER3, ER4), a span of the second dead zone being selectable from among a plurality of predetermined values (C2, C3, C4).

With this configuration, phase comparisons are performed multiple times during one period of the reference signal, so locking time (start-up) is shortened. By making the span of the second dead zone selectable from among a plurality of values (C2, C3, C4), it is possible to set, for each of the phase comparators (or for each of the error signals), a phase difference at which supply of the error signal to the control voltage generating means such as a low-pass filter is stopped.

The phase comparison means may be comprised of a plurality of phase comparators at least one of which is provided with a plurality of selectable delay circuits (60, 61, 62, 74, 75, 76) for delaying the input signal.

With this configuration, since all the phase comparators are caused to output the error signals to the control voltage generating means to increase the number of phase comparisons at the start of the phase lock operation, the lock-up time is shortened. Furthermore, by reducing gradually the number of the phase comparators outputting the error signals as the locked state approaches in accordance with the spans of their dead zones, interference between the outputs of the phase comparators can be avoided.

Each of a plurality of the delay circuits may be comprised of inverters connected in series.

One inverter component has its own delay time. Accordingly, any delay time can be obtained easily by selecting the number of inverters connected in series.

By connecting selection circuits to the outputs of a plurality of the delay circuits, it is possible to select the output of any delay circuit connected to the selection circuit that is supplied with a specific control signal.

That is, it is possible to select one of the dead zones by supplying a specific control signal to one of the selection circuits to select one of the delay circuits. The control signal is a signal maintained at the H level or the H level, and therefore any precise gate-opening/closing timing previously required are unnecessary. Accordingly, interference between the outputs of the phase comparators due to shift of that timing can be avoided.

A plurality of the delay circuits may be comprised of a plurality of delay circuits (60, 61, 62) for delaying the incoming reference signal and a plurality of delay circuits (74, 75, 76) for delaying the incoming feedback signal.

With this configuration, the delay circuit 60 (to which the reference signal is input) and the delay circuit 75 (to which the feedback signal is input) can be selected in the phase comparator 68, for example. In this case, since the points at which the output voltage becomes zero are the points B53 and A52 (FIG. 9), the dead zone of the phase comparator 68 ranges from the point B53 to the point A52. As explained above, it is possible to set a dead zone as desired for letting the output voltage be zero as long as the phase difference is between a specific negative point (B53, for example) and a specific positive point (A52, for example).

The PLL device according to the fourth embodiment of the invention includes:

means (6) for generating a plurality of reference signals (FR1, FR2, FR3, FR4) having mutually differing phases; a single variable frequency divider or a plurality of variable frequency dividers (11, 12, 13, 14) for dividing, in synchronization with the phases of a plurality of the reference signals, a frequency of an output (FO) of a voltage-controlled oscillator (15) that produces a signal having a frequency responsive to a control voltage (CV) supplied to generate a plurality of feedback signals (FV1, FV2, FV3, FV4) having mutually differing phases;

a phase comparison means comprised of a single phase comparator or a plurality of phase comparators (7, 17, 8, 18, 9, 19, 10, 20) for comparing phases between the reference signals and the feedback signals corresponding to the reference signals to produce a plurality of error signals (ER1, ER2, ER3, ER4);

a control voltage generating means (21) for producing the control voltage (CV) to be supplied to the voltage-controlled oscillator from the error signals output from the phase comparison means; and

a control means (26 to 31) for setting, in synchronization with the phases of a plurality of the reference signals (FR1, FR2, FR3, FR4), outputting periods (S1, S2, S3 . . . ) during which the phase comparison means outputs a plurality of the error signals (ER1, ER2, ER3, ER4) to the control voltage generating means.

Since the outputting periods of the error signals are set in synchronization with the phases of a plurality of the reference signals as above, interference between a plurality of the error signals can be avoided. Furthermore, since phase comparisons are performed multiple times during one period of the reference signal, the lock-up time is shortened.

It is possible to set the outputting periods such that they do not overlap with each other.

If the outputting periods do not overlap with each other, only one error signal is output to the control voltage generating means during one outputting period without exception. Thus, interference between a plurality of the error signals can be avoided with reliability. Accordingly, lock is established smoothly and the lock-up time is shortened.

A suspension period (R1, R2, R3, R4, R5) during which productions of the error signals are all stopped may be interposed between neighboring outputting periods.

If such suspension periods during which productions of the error signals are all stopped are provided, the output of the phase comparator 8 during, for example, the outputting period T2, is not affected by the outputs of the phase comparators 7 and 9 during the outputting periods T1 and T3. Although the components constituting the PLL device have delay elements, it is possible to avoid the output of the phase comparator (8) from being affected by the outputs of the other phase comparators (7, 9, for example) by interposing the suspension period between neighboring outputting periods.

The rising or falling edges of the reference signals may be situated at approximately the centers of the outputting periods.

With this configuration, the outputting periods are set correctly in accordance with the phases of the corresponding reference signals. Accordingly, interference between the error signals can be avoided with reliability. As a result, an excess of the output signal over a target frequency (overshoot) is reduced and the lock-up time is shortened correspondingly.

The PLL device according to the fifth embodiment of the invention includes:

a voltage-controlled oscillator (102) producing an output signal of a frequency responsive to a control voltage (CV) supplied;

a variable frequency divider (103) dividing a frequency of the output signal (FO) of the voltage-controlled oscillator to produce a feedback signal of a frequency which is 1/N (N being a positive integer) of the frequency of the output signal, a phase comparator (106) comparing phases between the feedback signal and the reference signal;

a charge pump (109) outputting an error signal (PU, PD) in response to a comparison result of the phase comparator, a low-pass filter (110) filtering the error signal supplied from the charge pump to produce the control voltage; and

a control means (104, 105, 111, 117, 118) controlling a gain of the charge pump in accordance with a value of the N.

With this configuration, it is possible to maintain an overall gain of the PLL device, which is determined by a gain of the charge pump and a gain of the variable frequency divider, at a constant value which is independent of the value of the frequency-division ratio N. Accordingly, it is possible to prevent the overall gain of the PLL device from lowering when the frequency-division ratio N of the variable frequency divider is changed to a larger value.

The variant of the PLL device according to the fifth embodiment of the invention includes:

a voltage-controlled oscillator (102) producing an output signal of a frequency responsive to a control voltage (CV) supplied;

a variable frequency divider (103) dividing a frequency of the output signal (FO) of the voltage-controlled oscillator to produce a feedback signal of a frequency which is 1/N (N being a positive integer) of the frequency of the output signal, a phase comparator (106) comparing phases between the feedback signal and the reference signal to output an error signal (PU, PD);

a charge pump (109) outputting a first voltage (GND) when the feedback signal leads the reference signal and outputting a second voltage (VDD) when the feedback signal lags the reference signal;

a low-pass filter (110) filtering an output of the charge pump to produce the control voltage; and

a control means (104, 105, 111, 117, 118) exercising control for maintaining a current flowing between the charge pump and the low-pass filter at a value in accordance with a value of the N.

With this configuration, it is possible to maintain an overall gain of the PLL device, which is determined by a gain of the charge pump and a gain of the variable frequency divider, at a constant value which is independent of the value of the N. Accordingly, the natural angular frequency and the damping factor determined by the overall gain are maintained at their optimum values independently of the value of the N. As a consequence, degradation of the stability and converging speed of the PLL device due to change of the frequency-division ratio N can be avoided.

The control means may include a control unit (104) for computing the value of the N in response to a command from outside, a latch circuit (105) for storing a digital signal corresponding to the value of the N, and a D/A converter (111) for converting the digital signal into a voltage signal (D) to be supplied to the charge pump.

Since the frequency-division ratio N (digital value) supplied from the control unit to the latch circuit is converted into an analog value, it is possible to supply the charge with the voltage that is precisely proportional to the frequency-division ratio N.

The charge pump may include a first switching unit (Q7) connected between an output terminal (116) of the charge pump and a terminal of the first voltage (GND), conductivity of the first switching unit being controlled by the error signal (PD) output from the phase comparator, and a first mirror circuit (117) for maintaining, at a value in accordance with the voltage signal (D) supplied from the D/A converter, a current (I) flowing into the first switching unit from the low-pass filter through the output terminal (116) when the first switching unit turns on.

When the first switching unit turns on (for example, when the pump-down signal PD at the L level is output), a current depending on the voltage output from the D/A converter flows through the first mirror circuit, and the same current flows through the first switching unit, and accordingly a current of the same value flows into an output terminal of the charge pump from the low-pass filter, thereby enabling an accurate current control.

The charge pump may also include a second switching unit (Q6) connected between the output terminal (116) of the charge pump and a terminal of the second voltage (VDD), conductivity of the second switching unit being controlled by the error signal (PU) output from the phase comparator, and a second mirror circuit (118) for maintaining, at a value in accordance with the voltage signal (D) supplied from the D/A converter, a current (I) flowing into the low-pass filter from the second switching unit through the output terminal (116) when the second switching unit turns on.

When the second switching unit turns on (for example, when the pump-down signal PU at the L level is output), a current depending on the voltage output from the D/A converter flows through the second mirror circuit, and the same current flows through the second switching unit, and accordingly a current of the same value flows into the low-pass filter from the output terminal of the charge pump, thereby enabling an accurate current control.

1. A PLL device comprising:
means (6) for generating a plurality of reference signals (FR1, FR2, FR3, FR4) having mutually differing phases;
a single variable frequency divider or a plurality of variable frequency dividers (11, 12, 13, 14) for dividing, in synchronization with phases of a plurality of the reference signals, a frequency of an output signal (FO) of a voltage controlled oscillator (15) that produces a signal having a frequency responsive to a control voltage (CV) supplied to generate a plurality of feedback signals (FV1, FV2, FV3, FV4) having mutually differing phases;
a phase comparison means comprised of a single phase comparator or a plurality of phase comparators (57, 17, 58, 18, 59, 19, 60, 20) for comparing phases between the reference signals and the feedback signals corresponding to the reference signals to produce a plurality of error signals (ER1, ER2, ER3, ER4); and
a control voltage generating means (21) for producing the control voltage (CV) to be supplied to the voltage-controlled oscillator from the error signals output from the phase comparison means;
wherein the phase comparison means has a first dead zone (D1) used for producing at least one specific error signal (ER1) that is one of a plurality of the error signals, and a second dead zone (D2) used for producing the other error signals (ER2, ER3, ER4); and
wherein the phase comparison means comprises a first phase comparator (57) having a smaller dead zone and a second phase comparator (58, 59, 60) having a larger dead zone, both the first phase comparator and the second phase comparator supplying the error signals to the control voltage generating means (21) while phase difference between the output signal (FO) and the reference signal (FR) is large, only the first phase comparator supplying the error signal to the control voltage generating means after the phase difference becomes small.

2. A PLL device according to claim 5, in which the second phase comparator (58, 59, 60) is provided with a first delay circuit (40) for delaying an incoming reference signal and a second delay circuit (47) for delaying an incoming feedback signal.

3. A PLL device comprising:
means (6) for generating a plurality of reference signals (FR1, FR2, FR3, FR4) having mutually differing phases;
a single variable frequency divider or a plurality of variable frequency dividers (11, 12, 13, 14) for dividing, in synchronization with phases of a plurality of the reference signals, a frequency of an output signal (FO) of a voltage controlled oscillator (15) that produces a signal having a frequency responsive to a control voltage (CV) supplied to generate a plurality of feedback signals (FV1, FV2, FV3, FV4) having mutually differing phases;
a phase comparison means (67, 17, 68, 18, 69, 19, 70, 20) for comparing phases between the reference signals and the feedback signals corresponding to the reference signals to produce a plurality of error signals (ER1, ER2, ER3, ER4); and
a control voltage generating means (21) for producing the control voltage (CV) to be supplied to the voltage-controlled oscillator from the error signals output from the phase comparison means;
wherein the phase comparison means includes a first phase comparator (67, 17) having a first dead zone (C1) used for producing at least one specific error signal (ER1) that is one of a plurality of the error signals, and a plurality of second phase comparators (68, 18, 69, 19, 70, 20) having a second dead zone (C2, C3, C4) used for producing the other error signals (ER2, ER3, ER4), a span of the second dead zone being selectable from among a plurality of predetermined values (C2, C3, C4); and
wherein both the first phase comparator and at least one of the second phase comparators supply the error signals to the control voltage generating means (21) while phase difference between the output signal (FO) and the reference signal (FR) is large, and only the first phase comparator supplies the error signal to the control voltage generating means after the phase difference becomes small.

4. A PLL device according to claim 8, in which at least one of a plurality of the second phase comparators is provided with a plurality of selectable delay circuits (60, 61, 62, 74, 75, 76) for delaying an input signal.

5. A PLL device according to claim 9, in which a plurality of the delay circuits are comprised of inverters connected in series.

6. A PLL device according to claim 9 or 10, in which selection circuits are connected to outputs of a plurality of the delay circuits so that an output of any delay circuit connected to a selection circuit supplied with a specific control signal can be selected.

7. A PLL device according to any one of claims 9 to 11, in which a plurality of the delay circuits comprise a plurality of delay circuits (60, 61, 62) for delaying an incoming reference signal and a plurality of delay circuits (74, 75, 76) for delaying an incoming feedback signal.

8. A PLL device comprising:
means (6) for generating a plurality of reference signals (FR1, FR2, FR3, FR4) having mutually differing phases;
a single variable frequency divider or a plurality of variable frequency dividers (11, 12, 13, 14) for dividing, in synchronization with phases of a plurality of the reference signals, a frequency of an output signal (FO) of a voltage-controlled oscillator (15) that produces a signal having a frequency responsive to a control voltage (CV) supplied to generate a plurality of feedback signals (FV1, FV2, FV3, FV4) having mutually differing phases;
a phase comparison means comprised of a single phase comparator or a plurality of phase comparators (7, 17, 8, 18, 9, 19, 10, 20) for comparing phases between the reference signals and the feedback signals corresponding to the reference signals to produce a plurality of error signals (ER1, ER2, ER3, ER4),
a control voltage generating means (21) for producing the control voltage (CV) to be supplied to the voltage-controlled oscillator from the error signals output from the phase comparison means; and
a control means (26 to 31) for setting, in synchronization with the phases of a plurality of the reference signals (FR1, FR2, FR3, FR4), outputting periods (S1, S2, S3 . . . ) during which the phase comparison means outputs a plurality of the error signals (ER1, ER2, ER3, ER4) to the control voltage generating means.

9. A PLL device according to claim 13, in which the outputting periods do not overlap with each other.

10. A PLL device according to claim 14, in which a suspension period (R1, R2, R3, R4, R5) during which productions of the error signals are all stopped is interposed between neighboring outputting periods.

11. A PLL device according to any one of claims 13 to 15, in which rising or falling edges of the reference signals are situated at approximately enters of the outputting periods respective

12. A PLL device comprising:
a voltage-controlled oscillator (102) producing an output signal of a frequency responsive to a control voltage (CV) supplied;
a variable frequency divider (103) dividing a frequency of the output signal (FO) of the voltage-controlled oscillator to produce a feedback signal of a frequency which is 1/N (N being a positive integer) of the frequency of the output signal, a phase comparator (106) comparing phases between the feedback signal and the reference signal;
a charge pump (109) outputting an error signal (PU, PD) in response to a comparison result of the phase comparator, a low-pass filter (110) filtering the error signal supplied from the charge pump to produce the control voltage; and
a control means (104, 105, 111, 117, 118) controlling a gain of the charge pump in accordance with a value of the N.

13. A PLL device comprising:
a voltage-controlled oscillator (102) producing an output signal of a frequency responsive to a control voltage (CV) supplied;
a variable frequency divider (103) dividing a frequency of the output signal (FO) of the voltage-controlled oscillator to produce a feedback signal of a frequency which is 1/N (N being a positive integer) of the frequency of the output signal, a phase comparator (106) comparing phases between the feedback signal and the reference signal to output an error signal (PU, PD);
a charge pump (109) outputting a first voltage (GND) when the feedback signal leads the reference signal and outputting a second voltage (VDD) when the feedback signal lags the reference signal;
a low-pass filter (110) filtering an output of the charge pump to produce the control voltage; and
a control means (104, 105, 111, 117, 118) for maintaining a current flowing between the charge pump and the low-pass filter at a value in accordance with a value of the N;
wherein the control means includes a control unit (104) for computing the value of the N in response to a command from outside, a latch circuit (105) for storing a digital signal corresponding to the value of the N, and a D/A converter (111) for converting the digital signal into a voltage signal (D) to be supplied to the charge pump;
wherein the charge pump includes a first switching unit (Q7) connected between an output terminal (116) of the charge pump and a terminal of the first voltage (GND), conductivity of the first switching unit being controlled by the error signal (PD) output from the phase comparator, and a first mirror circuit (117) for maintaining, at a value in accordance with the voltage signal (D) supplied from the D/A converter, a current (I) flowing into the first switching unit from the low-pass filter through the output terminal (116) when the first switching unit turns on; and
wherein the charge pump further includes a second switching unit (Q6) connected between the output terminal (116) of the charge pump and a terminal of the second voltage (VDD), conductivity of the second switching unit being controlled by the error signal (PU) output from the phase comparator, and a second mirror circuit (118) for maintaining, at a value in accordance with the voltage signal (D) supplied from the D/A converter, a current (I) flowing into the low-pass filter from the second switching unit through the output terminal (116) when the second switching unit turns on.
